(19) United States
(12) Patent Application Publication
(10) Pub. No.: US 2010/0001744 A1
(43) Pub. Date: Jan. 7, 2010

(54) STANDING WAVE MEASURING UNIT AND STANDING WAVE MEASURING METHOD IN WAVEGUIDE, ELECTROMAGNETIC WAVE UTILIZATION APPARATUS, PLASMA PROCESSING APPARATUS AND PLASMA PROCESSING METHOD

(75) Inventors: Masaki Hirayama, Miyagi (JP); Tadahiro Ohmi, Miyagi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignees: Tokyo Electron Limited, Minato-ku, Tokyo (JP); Tohoku University, Sendai-shi, Miyagi-ken (JP)

(21) Appl. No.: 12/375,225

(22) PCT Filed: Jul. 18, 2007
(86) PCT No.: PCT/JP2007/064177

§ 371 Date: Jan. 27, 2009

(30) Foreign Application Priority Data
Jul. 28, 2006 (JP) 2006-206168

(51) Int. Cl. G01R 27/32

(52) U.S. Cl. 324/645; 374/45

(57) ABSTRACT

[Problem] To precisely measure a standing wave to be an indication for comprehending a guide wavelength λg or the like in a waveguide.

[Means for Solving] A distribution of temperatures is detected in a conductive member forming at least a part of pipe walls of a waveguide with respect to a longitudinal direction of a waveguide which propagates an electromagnetic wave, and a standing wave generated in the waveguide is measured based on the temperature distribution. The temperature distribution in the conductive member with respect to the longitudinal direction of the waveguide can be measured precisely with a plurality of temperature sensors disposed along the longitudinal direction of the waveguide, a temperature sensor which moves along the longitudinal direction of the waveguide, or an infrared camera.

### TECHNICAL FIELD

The present invention relates to a measuring unit and a measuring method for measuring a standing wave generated in a waveguide which propagates an electromagnetic wave, and further relates to an electromagnetic wave utilization apparatus and a plasma processing apparatus and method using a microwave.

### BACKGROUND ART

In a manufacturing process of, for example, an LCD apparatus or the like, there is used an apparatus which generates plasma in a processing chamber using a microwave as an electromagnetic wave, and performs CVD processing, etching processing, or the like on an LCD substrate. As such a plasma processing apparatus, there is known one having plural waveguides arranged in parallel above a processing chamber (refer to, for example, Patent Documents 1, 2). Plural slots are arranged and opened at even intervals in lower faces of these waveguides, and moreover, dielectrics having plate shapes are provided along the lower faces of the waveguides. Then the apparatus is structured such that microwaves in the waveguides are propagated to surfaces of the dielectrics through the slots so as to turn a predetermined gas (rare gas for plasma excitation and/or gas for plasma processing) supplied into the processing chamber into plasma by energy (electromagnetic fields) of the microwaves.

### [Patent Document 1] Japanese Patent Application Laid-Open No. 2004-200646

### [Patent Document 2] Japanese Patent Application Laid-Open No. 2004-152876

### DISCLOSURE OF THE INVENTION

### Problems to Be Solved by the Invention

In these Patent Documents 1, 2, intervals between the slots are set to predetermined even intervals (intervals which are each approximately half (λg′/2) a guide wavelength λg′ in initial setting) so that the microwaves can be propagated efficiently from plural slots provided in the lower faces of the waveguides. However, an actual guide wavelength λg of a microwave propagating in a waveguide is not constant, and the guide wavelength λg has a characteristic to change when the impedance in a processing chamber (inside chamber) is changed due to the condition, for example the gas type, pressure, or the like, of plasma processing performed in the processing chamber. Accordingly, when plural slots are formed at predetermined even intervals in the lower faces of the waveguides as in Patent Documents 1, 2, the guide wavelength λg changes by the condition of plasma processing (impedance), and thereby a displacement occurs between the guide wavelength λg′ in initial setting and the actual guide wavelength λg. Consequently, the microwaves can no longer be propagated evenly into the processing chamber through the dielectrics from the respective plural slots.

The guide wavelength λg, however, cannot be measured easily from the outside of the waveguides. Conventionally, for example, there is known a method in which a slit is formed in an H face (wide wall face) of a rectangular waveguide in a waveguide longitudinal direction, and an electric field probe is inserted in the waveguide through the slit and moved along the slit so as to measure an electric field intensity distribution. However, when the slit is formed in a waveguide, there is a concern that a microwave leaks to the outside therethrough. Further, there is a possibility of negatively affecting the electromagnetic field distribution in the waveguide by inserting the electric field probe. Further, in the plasma processing apparatus generating plasma in a processing chamber using microwaves, it is practically impossible in many cases to form the slit in an H face of a waveguide and insert the electric field probe due to constraints in the apparatus. Accordingly, measurement of the guide wavelength λg in the plasma processing apparatus is difficult in reality.

On the other hand, in a waveguide, generally, an incident wave and a reflection wave of microwaves interfere with each other and generate a standing wave. Although varying due to the influence of entrance of a microwave to the processing vessel via a slot, the influence of a reflection wave entering the waveguide via a slot, and the like, the period of this standing wave (equivalent to the interval between adjacent antinode portions (or the interval between adjacent node portions) of the standing wave) can be a measure of the guide wavelength λg. The period of the standing wave can be also assumed as approximately equal to half λg/2 the guide wavelength λg, which is the wavelength of a microwave propagating in the waveguide.

Further, by measuring this standing wave, it is possible to find a frequency, a standing wave ratio, a propagation constant, an attenuation constant, a phase constant, and the like other than the guide wavelength. Furthermore, it is also possible to find a reflection coefficient, impedance, and the like of a load connected to the waveguide.

Therefore, an object of the present invention is to make it possible to accurately measure a standing wave as an indication for comprehending the guide wavelength λg or the like in a waveguide, and further to provide a plasma processing apparatus which propagates microwaves evenly into a processing chamber through dielectrics from plural respective slots.

### Means for Solving the Problems

To solve the above-described problems, according to the present invention, there is provided a standing wave measuring unit for measuring a standing wave generated in a waveguide which propagates an electromagnetic wave, the unit having a conductive member disposed along a longitudinal direction of the waveguide to form at least a part of pipe walls of the waveguide, and a temperature detecting means for detecting a temperature of the conductive member at plural positions in the longitudinal direction of the waveguide.

In this standing wave measuring unit, the waveguide is, for example, a rectangular waveguide, and the conductive member may be disposed on a narrow wall face of the rectangular waveguide. Further, the conductive member has, for example, a plate shape and a thickness d of the conductive member satisfies a relationship of following expression (1) when an angular frequency of an electromagnetic wave propagating in the waveguide is ω, magnetic permeability of the conductive member in which a temperature is measured is μ, and resistivity thereof is ρ.

3×(2ρ/(ωμ))^{1/2}<d<14×(2ρ/(ωμ))^{1/2} (1)

Further, the conductive member has, for example, a plate shape, and a plurality of holes are formed therein. Further, the conductive member is, for example, a mesh formed by metal. Further, the conductive member has, for example, a structure in which a plurality of conductive parts extending in a direction orthogonal to the longitudinal direction of the waveguide are disposed in parallel at predetermined intervals.

Further, a temperature regulating mechanism controlling a temperature in a periphery of the conductive member may be included.

The temperature detecting unit may be capable of measuring a temperature in a periphery of the conductive member. Further, another temperature detecting means for measuring a temperature in a periphery of the conductive member may be included.

Further, the temperature detecting means includes, for example, a temperature sensor detecting a temperature of the conductive member, a measuring circuit processing an electric signal from the temperature sensor, and a wiring electrically connecting the temperature sensor and the measuring circuit, and a plurality of the temperature sensors are disposed along the longitudinal direction of the waveguide. In this case, the wiring includes, for example, a heat transfer suppressing unit suppressing transfer of heat via the wiring. Further, for example, the temperature sensor includes a plurality of electrodes, and at least one of the plurality of electrodes is electrically short-circuited to the waveguide. Further, for example, a printed circuit board including the temperature sensor is attached to the conductive member. Further, for example, the temperature sensor is disposed outside the waveguide. Further, for example, a heat transfer path transferring a temperature of the conductive member to the temperature sensor is included. In addition, the temperature sensor is, for example, one of thermistor, resistance temperature sensor, diode, transistor, temperature measuring IC, thermocouple, and Peltier element.

Further, the temperature detecting unit is, for example, structured to move along the longitudinal direction of the waveguide one or more sensors detecting a temperature of the conductive member. In this case, the temperature sensor may be disposed outside the waveguide. Further, the temperature sensor can be an infrared temperature sensor.

Further, the temperature detecting means is, for example, an infrared camera.

In addition, the standing wave measuring unit according to the present invention is capable of measuring one of guide wavelength, frequency, standing wave ratio, propagation constant, attenuation constant, phase constant, propagation mode, incident power, reflection power, and transmitted power of an electromagnetic wave propagating in the waveguide or one of reflection coefficient and impedance of a load connected to the waveguide.

Furthermore, a plurality of positions in the longitudinal direction of the waveguide may be fixed, and a plurality of positions in the longitudinal direction of the waveguide may be movable.

Further, according to the present invention, there is provided a standing wave measuring method for measuring a standing wave generated in a waveguide which propagates an electromagnetic wave, the method including detecting a distribution of temperatures in a conductive member forming at least a part of pipe walls of the waveguide with respect to a longitudinal direction of the waveguide, and measuring a standing wave based on the temperature distribution. In addition, a reference temperature of the conductive member may be measured in a state that no electromagnetic wave is propagating in the waveguide, and the distribution of temperatures in the conductive member may be detected by a temperature difference from the reference temperature.

Further, according to the present invention, there is provided a standing wave measuring method of measuring a standing wave generated in a waveguide which propagates an electromagnetic wave, the method including detecting an electric current flowing in a conductive member forming at least a part of pipe walls of the waveguide, and measuring a standing wave based on a distribution of the current with respect to a longitudinal direction of the waveguide.

These standing wave measuring methods according to the present invention is capable of measuring one of guide wavelength, frequency, standing wave ratio, propagation constant, attenuation constant, phase constant, propagation mode, incident power, reflection power, and transmitted power of an electromagnetic wave propagating in the waveguide or one of reflection coefficient and impedance of a load connected to the waveguide.

Further, according to the present invention, there is provided a standing wave measuring unit for measuring a standing wave generated in a waveguide which propagates an electromagnetic wave, the unit having a conductive member disposed along a longitudinal direction of the waveguide to form at least a part of pipe walls of the waveguide, and a current detecting means for detecting a current flowing in the conductive member at plural positions in the longitudinal direction of the waveguide.

Further, according to the present invention, there is provided an electromagnetic wave utilization apparatus including an electromagnetic wave supply source for generating an electromagnetic wave, a waveguide for propagating an electromagnetic wave, and a wave utilization means for utilizing the electromagnetic wave supplied from the waveguide to perform predetermined processing, in which the waveguide is provided with a standing wave measuring unit according to the present invention.

Furthermore, according to the present invention, there is provided a plasma processing apparatus provided with a processing vessel in which plasma is excited for substrate processing, a microwave supply source supplying a microwave for exciting plasma in the processing vessel, a waveguide in which a plurality of slots are opened and which is connected to the microwave supply source, and a dielectric plate which propagates a microwave emitted from the slots to plasma, the apparatus including the standing wave measuring unit according to the present invention for measuring a standing wave generated in the waveguide.

This plasma processing apparatus may further include a wavelength control mechanism controlling a wavelength of a microwave propagated in the waveguide. In this case, the waveguide is for example a rectangular waveguide, and the wavelength control mechanism is structured to move a narrow wall face of the rectangular waveguide vertically with respect to a propagating direction of a microwave in the waveguide.

Further, according to the present invention, there is provided a plasma processing method for performing substrate processing by emitting a microwave propagated in a waveguide from a plurality of slots opened in the waveguide and propagating the microwave to a dielectric plate and exciting plasma in a processing vessel, the method including detecting a distribution of temperatures in a conductive member forming at least a part of pipe walls of the waveguide with respect to a longitudinal direction of the waveguide and measuring a standing wave based on the temperature distribution, and controlling a wavelength of a microwave propagated in the waveguide based on the measured standing wave.

In this plasma processing method, for example, the waveguide is a rectangular waveguide, and the wavelength of the microwave propagated in the waveguide may be controlled by moving a narrow wall face of the rectangular waveguide vertically with respect to a propagating direction of a microwave in the waveguide. In this case, for example, the wavelength of the microwave propagated in the waveguide can be controlled so that antinode portions of a standing wave generated in the waveguide match with the slots.

### EFFECT OF THE INVENTION

With a standing wave measuring unit and measuring method according to the present invention, it becomes possible to measure a standing wave by detecting a temperature of a conductive member forming at least a part of pipe walls of a waveguide with respect to a longitudinal direction of the waveguide. A distribution of temperatures in the conductive member with respect to the longitudinal direction of the waveguide can be measured precisely with a plurality of temperature sensors disposed along the longitudinal direction of the waveguide, a temperature sensor which moves along the longitudinal direction of the waveguide, or an infrared camera. Then, a guide wavelength, and a frequency, a standing wave ratio, a propagation constant, an attenuation constant, a phase constant, and the like thereof can be found based on the period of the measured standing wave. Furthermore, a reflection coefficient, impedance, and the like of a load connected to the waveguide can be found.

Further, with a plasma processing apparatus and measuring method according to the present invention, an interval (λg/2) which is half a wavelength λg of a microwave can be matched with the interval (λg′/2) between slots to eliminate a displacement therebetween by controlling the wavelength of a microwave propagated in the waveguide based on the period of a measured standing wave, and hence microwaves can be propagated efficiently into a processing chamber via dielectrics from respective plural slots.

### BRIEF DESCRIPTION OF THE DRAWINGS

FIG. 1 A perspective view of a waveguide having a standing wave measuring unit according to an embodiment of the present invention.

FIG. 2 A partial enlargement of the standing wave measuring unit according to the embodiment of the present invention.

FIG. 3 An enlarged view of a cross section taken along a line A-A in FIG. 2.

FIG. 4 An explanatory diagram of electromagnetic fields formed in a rectangular waveguide and E-face currents flowing on upper and lower faces of the rectangular waveguide.

FIG. 5 A conceptual diagram of a positional relationship between power supply and a load with respect to the waveguide.

FIG. 6 An explanatory diagram of a standing wave in the waveguide.

FIG. 7 An explanatory diagram (upper part) of a temperature distribution in a conductive member and a vertical cross-sectional view (lower part) of the waveguide.

FIG. 8 An explanatory view of a standing wave measuring unit according to a second embodiment of the present invention.

FIG. 9 An explanatory view of a conductive member structured having conductive parts which extend in a direction orthogonal to a longitudinal direction of the rectangular waveguide and are disposed in parallel at predetermined even intervals.

FIG. 10 An explanatory view of a conductive member formed to have a mesh structure.

FIG. 11 An explanatory view of a conductive member formed to have a punching metal structure.

FIG. 12 A vertical cross-sectional view (X-X cross section in FIG. 13) showing a schematic structure of a plasma processing apparatus according to an embodiment of the present invention.

FIG. 13 A bottom view of a lid.

FIG. 14 A partially enlarged vertical cross-sectional view (Y-Y cross section in FIG. 13) of the lid.

FIG. 15 An enlarged view of a dielectric seen from a bottom side of the lid.

FIG. 16 A vertical cross section of the dielectric taken along a line X-X in FIG. 15.

FIG. 17 A graph showing results of examples of changing the height of an upper face of a rectangular waveguide and studying changes of a film thickness with respect to the distance from a rear end of the rectangular waveguide.

FIG. 18 An explanatory view schematically showing positions of antinode portions of a standing wave generated in the rectangular waveguide when the height of the upper face of the rectangular waveguide is changed.

FIG. 19 A graph showing temperature changes in a conductive member with respect to a longitudinal direction of the rectangular waveguide when the height of the upper face of the rectangular waveguide is changed.

FIG. 20 A graph showing a relationship between guide wavelengths (actual measured values) and da by comparing with theoretical values.

### EXPLANATION OF CODES

E electric field
G substrate
H magnetic field
I E-face current
1 plasma processing apparatus
2 processing vessel
3 lid
4 processing chamber
10 susceptor
11 power feeding unit
12 heater
13 radio-frequency power supply
14 matching device
15 high-voltage DC power supply
16 coil
17 AC power supply
20 lift plate
21 cylinder
22 bellows
23 exhaust port
24 current plate
30 lid body
31 slot antenna
32 dielectric
33 O-ring
35 rectangular waveguide
36 dielectric member
40 microwave supply device
41 Y branch pipe
45 upper face
46 lift mechanism
50 cover
51 guide unit
52 lift unit
54 scale
55 guide rod
56 lift rod
57 nut
58 hole
60 guide
61 timing pulley
62 timing belt
63 rotation handle
66 printed circuit board
67a conductor
67 wiring pattern
68 through hole
69 thermistor
70 slot
71 dielectric member
75 beam
80a, 80b, 80c, 80d, 80e, 80f, 80g recess
81 wall face
85 gas injection port
90 gas pipe
91 cooling water pipe
95 gas supply source
100 argon gas supply source
101 silane gas supply source
102 hydrogen gas supply source
105 cooling water supply source
200 standing wave measuring unit
201 rectangular waveguide
202 conductive member
203 metal wall
204 printed circuit board
205 through hole
206 solder
208 thermistor
209, 210 electrode
211 wiring pattern
212 connector
213 cable
214 measuring circuit
217 cooling medium channel
218 shield

### BEST MODE FOR CARRYING OUT THE INVENTION

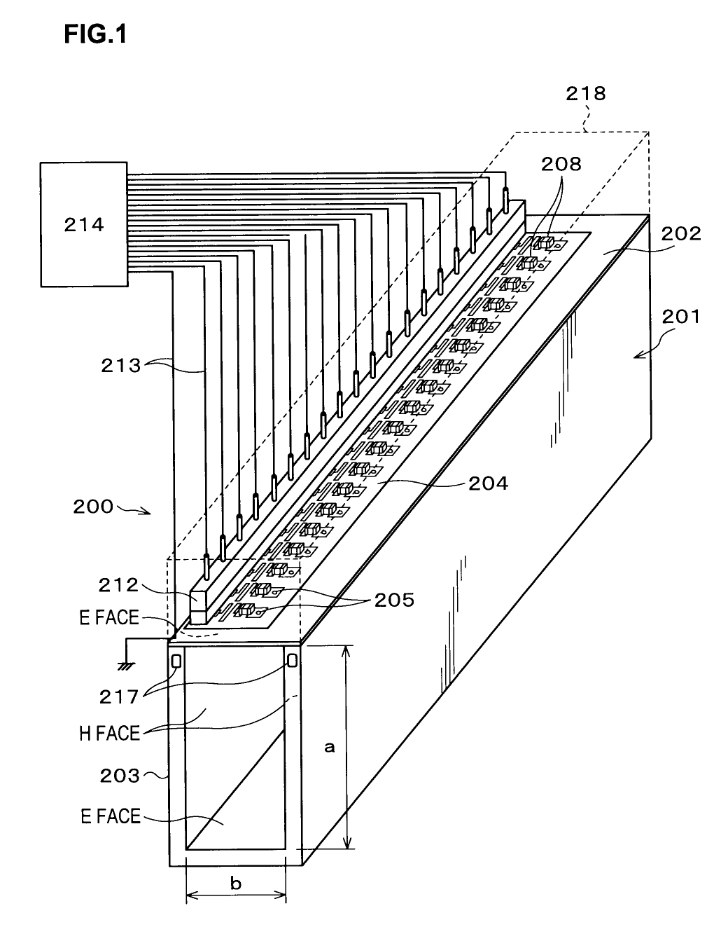

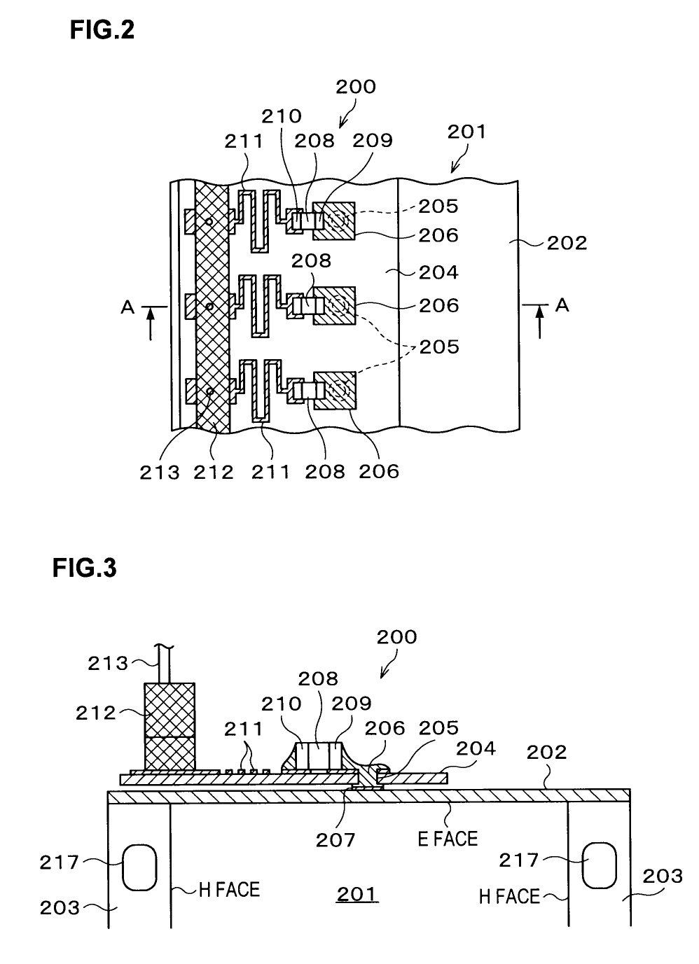

Hereinafter, preferred embodiments of the present invention will be explained. FIG. 1 is a perspective view of a waveguide having a standing wave measuring unit 200 according to an embodiment of the present invention. This standing wave measuring unit 200 is structured for measuring a distribution of standing waves generated in a rectangular waveguide 201 which propagates microwaves as electromagnetic waves. FIG. 2 is a plan view of the rectangular waveguide 201 for explaining the standing wave measuring unit 200. FIG. 3 is a cross-sectional view taken along a line A-A in FIG. 2. Note that in this description and the drawings, components having substantially the same functions and structures are given the same reference numerals, and duplicated explanations are omitted.

The shown rectangular waveguide 201 is structured having upper and lower faces as E faces (narrow wall faces) and left and right side faces as H faces (wide wall faces). The upper face out of the two E faces (narrow wall faces) of the rectangular waveguide 201 is formed by a conductive member 202 having a plate form, and the other faces (lower face and left and right side faces) are formed by aluminum metal walls 203. In addition, the conductive member 202 and the metal walls 203 are electrically short-circuited. The thickness of the conductive member 202 is 0.1 mm for example, and the material thereof is stainless steel for example. A printed circuit board 204 is provided on an upper portion of the conductive member 202. In the printed circuit board 204, plural through holes 205 penetrating the board are provided along a center line of the conductive member 202 at even intervals (4 mm intervals) in series in a longitudinal direction of the rectangular waveguide 201. The printed circuit board 204 and the conductive member 202 are thermally connected by solders 206 filled in the through holes 205. In these connection parts, gold plates 207 are provided on the surface of the conductive member 202, thereby ensuring the connection by the solders 206.

Thermistors 208 as temperature sensors are disposed in vicinities of respective through holes 205 on an upper face of the printed circuit board 204. The through holes 205 filled with the solders 206 are heat transfer paths for transferring temperatures of the conductive member 202 to the thermistors 208. When an electric current flows in the conductive member 202 by energy of a microwave propagating in the rectangular waveguide 201, the conductive member 202 heats up according to the magnitude of the current, and the generated heat is transferred to the thermistors 208 on the upper face of the printed circuit board 204 via the respective through holes 205. This causes the resistance values of the thermistors 208 to change, and thereby a temperature distribution in the conductive member 202 in the longitudinal direction of the rectangular waveguide 201 is detected electrically.

In this embodiment, as the thermistors 208, there are used chip-part ones of NTC type which have a negative temperature coefficient and have no lead wire. The size thereof is 1.6 mm long, 0.8 mm wide, and 0.8 mm high. Thus, using small chip parts (thermistors 208) as temperature sensors, the pitch between temperature measurement points (positions of the through holes 205) can be made narrow, and thus the temperature distribution in the conductive member 202 in the longitudinal direction of the rectangular waveguide 201 can be measured more minutely. Furthermore, the heat capacity of the temperature sensors (thermistors 208) can be suppressed small, and thus the response time can be shortened.

Incidentally, although the thermistors 208 are explained as the temperature sensors, resistance temperature sensors or thermocouples may be used as the temperature sensors. Further, diodes, bipolar transistors, junction-type field effect transistors, Peltier elements, temperature measuring ICs, or the like can be used as the temperature sensors. In this case, temperatures are converted from electrical signals using a phenomenon that a built-in voltage at a pn junction changes by a temperature.

A thermistor 208 has two electrodes 209, 210. One electrode 209 is connected electrically to a ground via the through hole 205 and the conductive member 202, and the other electrode 210 is connected electrically to a measuring circuit 214 via a copper wiring pattern 211 formed on the printed circuit board 204, a connector 212 and a cable 213.

When heat flows out to the outside through the wiring pattern 211 from a thermistor 208, the temperature of the thermistor 208 decreases, and a measured temperature becomes inaccurate. Accordingly, a heat transfer suppressing unit for suppressing heat transfer via wiring is formed in at least a part of the wiring pattern 211. In the shown example, the heat transfer suppressing unit is formed by making the entire wiring pattern 211 as a path that is as narrow and long as possible to be a shape that suppresses heat transfer, thereby suppressing the heat flowing out through the wiring pattern 211 from the thermistors 208. The thermal resistance of the wiring pattern 211 is in proportion to the length of the wiring and in reverse proportion to the width thereof. Since the narrow, long wiring pattern with large thermal resistance is disposed in a limited space on the substrate, it is desirable that the wiring pattern 211 is formed in an S coupling shape or the like. In addition, it is not always necessarily to form the entire wiring pattern 211 in the heat transfer suppressing unit, and for example a part of the wiring pattern 211 may be a shape capable of suppressing heat transfer.

On upper portions of the left and right side faces (wide wall faces) of the metal walls 203, heat medium channels 217 as a temperature regulating mechanism are formed. By making a flow of temperature regulating water at a constant temperature in these heat medium channels 217, the temperature around the conductive member 202 is regulated, and the temperature around the conductive member 202 is kept constant. Further, the space accommodating the printed circuit board 204 is covered by a shield 218, which suppresses entrance of noise from the outside.

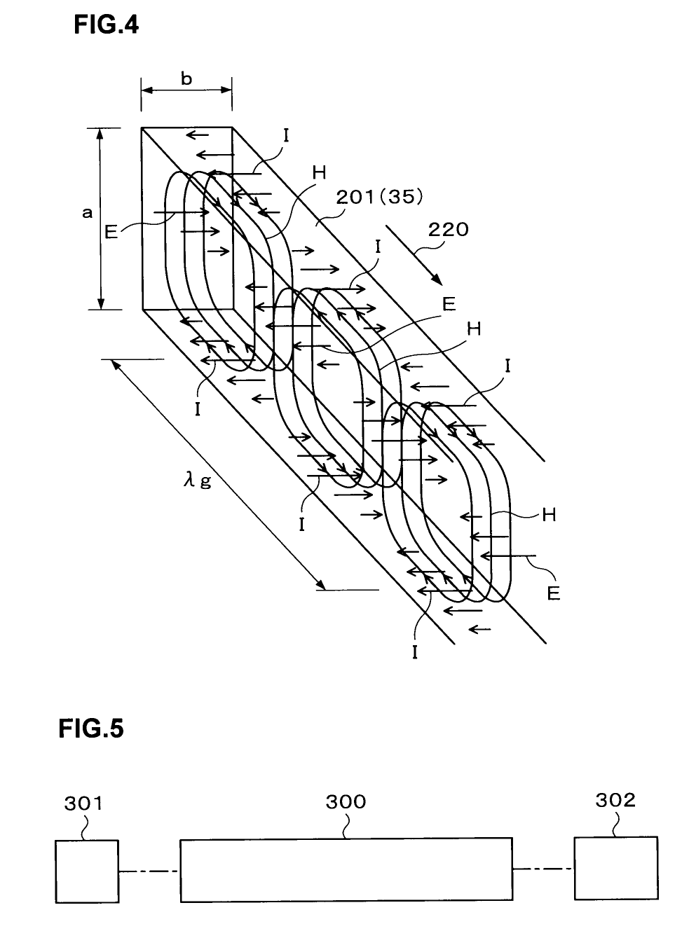

FIG. 4 shows an electromagnetic field distribution at a certain moment in TE₁₀ mode that is a basic mode of an electromagnetic wave (microwave) propagating in the rectangular waveguide 201. In the rectangular waveguide 201, vertical electric fields E are applied between the two H faces (wide wall faces) of a longitudinal direction 220 of the waveguide 201 in parallel to the E faces (narrow wall faces), and magnetic fields H in vertical shapes in parallel to the H faces and orthogonal to the electric fields E are formed. Further, inside the E faces, E-face currents I perpendicular to the waveguide longitudinal direction 220 flow. The E-face currents I become 0 (zero) at positions where the electric fields E are maximum, and conversely the E-face currents I become maximum at positions where the electric fields E are 0. Such an electromagnetic field in the waveguide proceeds in the waveguide longitudinal direction 220 over time while maintaining its distribution shape.

In general, an incident wave and a reflection wave propagating in a reverse direction thereof exist in a waveguide, and interference between the incident wave and the reflection wave generates a standing wave. For example, as shown in FIG. 5, when a power supply 301 with an angular frequency ω is connected inside a waveguide 300, an incident wave proceeds to a load 302 side from the power supply 301 and is reflected off the load 302 by a reflection coefficient Γ, and thereby a standing wave is formed in the waveguide 300. When a loss in the waveguide 300 is so small that it can be ignored, an E-face current due to the incident wave is expressed as Ae^{jβz}. Here, A is an amplitude of the E-face current due to the incident wave and is a complex number. β is a phase constant, and in a relationship with the guide wavelength λg of the following equation (2).

β=2π/λg (2)

On the other hand, the E-face current due to the reflection wave is the product of an incident wave and a reflection coefficient, and is expressed as ΓAe^{-jβz}. When a phase angle of the reflection coefficient Γ is φ, the reflection coefficient Γ can be written as the following equation (3).

Γ=|Γ|e^{jφ} (3)

Eventually, the E-face current I by the algebraic sum of the incident wave and the reflection wave becomes the following equation (4).

I=Ae^{jβz}(1+|Γ|e^{j(φ-2βz)} (4)

From the equation (4), the amplitude of a standing wave becomes the following equation (5).

|I|=|A∥1+|Γ|e^{j(φ-2βz)|} (5)

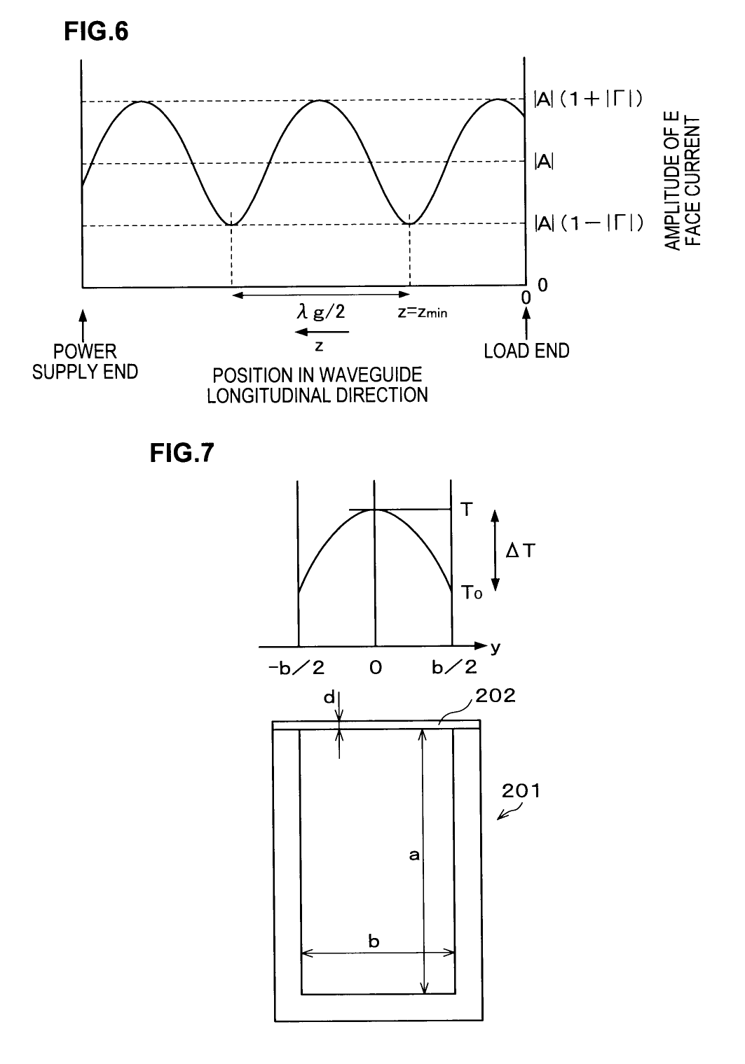

FIG. 6 shows an appearance of a standing wave of the E-face current. The standing wave of the E-face current repeats to increase and decrease periodically by the period of ½ of the guide wavelength λg (that is λg/2). That is, the guide wavelength λg can be obtained by doubling the interval between adjacent nodes or antinodes of the standing wave if they are known. (Incidentally, in a plasma processing apparatus 1 or the like which will be described later, due to the influence of microwaves emitted from the waveguides or reflection waves entering the waveguides from the outside, half (λg/2) the guide wavelength λg and the period of the standing wave do not match in the strict sense. However, the period of the standing wave is approximately equal to half λg/2 the guide wavelength λg which is the wavelength of a microwave propagating in the waveguide, and can be a measure of the guide wavelength λg. Accordingly, in the following, explanations are given assuming that the period of the standing wave is equal to half (λg/2) the guide wavelength λg.)

Here, the maximal value of amplitude of the E-face current is expressed as |I|ₘₐₓ, and the minimal value of amplitude of the E-face current is expressed as |I|ₘᵢₙ. The standing wave ratio (SWR) σ is defined as the following equation (6).

σ=|I|ₘₐₓ/|I|ₘᵢₙ (6)

Further, from the equations (5), (6), the following equation (7) is derived.

σ=(1+|Γ|)/(1−|Γ|) (7)

When the distance from the load 302 to the position of |I|ₘᵢₙ is zₘᵢₙ, the phase angle φ of the reflection coefficient Γ is expressed as the following equation (8).

φ=−π+4πzₘᵢₙ/λg (8)

Specifically, when the ratio of |I|ₘₐₓ to |I|ₘᵢₙ and the position of |I|ₘᵢₙ are known, the standing wave ratio σ and the reflection coefficient Γ (including amplitude and phase) can be obtained from the equations (6), (7), and (8). The load impedance Z is given by the following equation (9) using the reflection coefficient Γ.

Z=Z_{H}(1+Γ)/(1−Γ) (9)

Here, Z_{H} is a characteristic impedance of the waveguide 300.

Incident power Pᵢ to the load 302 can be obtained by the following equation (10).

Pᵢ=|A|²ab/4(2a/λg)²Z_{H} (10)

Here, a, b are the interval between the E faces and the interval between the H faces, respectively, as shown in FIG. 1.

Furthermore, reflection power Pᵣ and transmitted power Pₜ can be given by the following equations (11), (12), respectively.

Pᵣ/Pᵢ=|Γ|² (11)

Pₜ/Pᵢ=(1−|Γ|²) (12)

Therefore, when the incident power Pᵢ, the ratio of |I|ₘₐₓ to |I|ₘᵢₙ, and the position of |I|ₘᵢₙ are known, the reflection power Pᵣ and equivalent power Pₜ can be obtained. Further, when values of |I|ₘₐₓ and |I|ₘᵢₙ are known, the incident power Pᵢ can be obtained from the equation (10).

By the currents I flowing along the insides of the E faces of the rectangular waveguide 201 explained previously with FIG. 1 to FIG. 3, the conductive member 202 is heated by Joule heat and increases in temperature. When the conductive member 202 increases in temperature, heat quantities transferred from the left and right ends of the conductive member 202 to the metal walls 203 increase and sooner or later reach an equilibrium state. The temperature distribution in the conductive member 202 at this time is shown in FIG. 7. The temperature distribution in the conductive member 202 becomes a quadric curve on which the temperature is highest at a position on the center line (y=0) and lowest at both ends.

A temperature on the center line (y=0) of the conductive member 202 is T, and a temperature on an end portion (y=±b/2) is T₀. A temperature difference between them, ΔT=T−T₀ is given by the following equation (13).

ΔT=ρb²I²/(4dδk) (13)

Here, ρ, d, and k are the resistivity, thickness and thermal conductivity, respectively, of the conductive member 202. δ is a skin depth represented by the following equation (14).

δ=(2ρ/(ωμ))^{1/2} (14)

From the equation (13), it can be seen that the temperature difference ΔT is in proportion to the square of the E-face current I. Therefore, when the maximal value of the temperature difference is ΔTₘₐₓ and the minimal value is ΔTₘᵢₙ, the standing wave ratio (SWR) σ is expressed as the following equation (15) using the equation (6).

σ=(ΔTₘₐₓ/ΔTₘᵢₙ)^{1/2} (15)

From the temperature distribution in the conductive member 202 with respect to the waveguide longitudinal direction, the standing wave ratio σ is obtained using the equation (15). The guide wavelength λg is obtained by doubling the interval between positions where ΔT becomes a minimal value or the interval between positions where ΔT becomes a maximal value. The frequency of an electromagnetic wave propagating in the waveguide is obtained from the guide wavelength λg. Further, the reflection coefficient Γ (including amplitude and phase) is obtained from the equations (7), (8) and (15). The incident power Pᵢ is obtained using the equations (10) and (13) from the temperature distribution, but when the accuracy of the value of the incident power Pᵢ obtained in this manner is insufficient, it is desirable that correction is made using incident power measured by another power measuring method. When the incident power Pᵢ is known, the reflection power Pᵣ and equivalent power Pₜ are obtained from the equations (11) and (12).

In the foregoing, it is assumed that a loss in the waveguide is so small that it can be ignored. When it cannot be ignored, the following holds true. Here, a matched load is connected to the load side of the waveguide, and it is assumed that there is no reflection. The E-face current I can be expressed as the following equation (16).

I=Ae^{γz}=Ae^{α+jβ} (16)

Here, γ=α+jβ is propagation constant, and α is attenuation constant.

Taking absolute values of the both sides, the following equation (17) is obtained.

|I|/|A|=e^{α}∝(ΔT)^{1/2} (17)

From the temperature distribution in the conductive member 102, the attenuation constant α is obtained using the equation (17). Further, the phase constant β is obtained from the equation (2). Consequently, the propagation constant γ can be obtained.

In the foregoing, the case of the TE₁₀ mode in the rectangular waveguide is explained, but values of the parameters can be obtained by the same method even in a mode other than the TE₁₀ mode. Further, from the temperature distribution of the conductive member 202, it is possible to infer what propagation mode the propagation is occurring. Moreover, it is not limited to the rectangular waveguide, and the same measuring method can be applied to other waveguides, such as circular waveguides, coaxial waveguides, ridge waveguides and the like. By measuring the temperature distribution in the conductive member 202 in this manner, the guide wavelength, frequency, standing wave ratio, propagation constant, attenuation constant, phase constant, propagation mode, incident power, reflection power, and transmitted power of an electromagnetic wave propagating in the waveguide are obtained, and moreover the reflection coefficient and impedance of the load are obtained.

To measure the standing wave in the waveguide precisely in this embodiment, it is essential to measure the temperature difference ΔT precisely and to suppress the influence of the conductive member 202 to propagation of electromagnetic wave small. To measure the temperature difference ΔT precisely, it is desirable that the temperature difference ΔT is as large as possible when a desired E-face current flows. From the equation (13), the temperature difference ΔT is in reverse proportion to the thickness d of the conductive member 202, and thus it can be seen that the temperature difference ΔT becomes larger as the thickness d is made thinner.

However, when the thickness d is as thin as several times the skin depth of the electromagnetic wave expressed by the equation (14) or smaller, the walls forming the waveguide do not operate as complete conductive walls, and this affects propagation of electromagnetic waves in the waveguide. Thus, the thickness d cannot be made thinner needlessly. The degree of influence on the propagation of electromagnetic waves is expressed as exp(−d/δ). Mechanical precision or stability of a general waveguide is approximately 1 ppm at most, and thus the value of exp(−d/δ) of 1 ppm or larger will suffice. Further, by a general measuring instrument, accuracy of 5% or higher at lowest is required, and it is necessary that the value of exp(−d/δ) is 5% or smaller. From these conditions, the following expression (18) is obtained.

4<d/δ<14 (18)

Further, from the equations (14) and (18), the following expression (1) is obtained.

3×(2σ/(ωμ))^{1/2}<d<14×(2ρ/(ωμ))^{1/2} (1)

The standing wave measuring unit 200 of this embodiment is structured so as to measure a temperature T on the center line (position of y=0 of FIG. 7) of the conductive member 202. The temperature difference ΔT is obtained by subtracting the end portion (y=±b/2) temperature T₀ from the temperature T on the center line. Therefore, precise measurement cannot be performed when the end portion temperature T₀ as the reference temperature is unknown. In this embodiment, as shown in FIG. 1, the heat medium channels 217 are provided, and the flow of temperature regulating water at a constant temperature is made in these heat medium channels 217, to thereby keep the end portion temperature T₀ of the conductive member 202 constant.

To measure this end portion temperature T₀ in advance, the temperature T on the center line is measured by each thermistor 208 in a state that no electromagnetic wave is propagating in the rectangular waveguide 201. At this time, there is no movement of temperature to/from the conductive member 202, and thus the temperature T on the center line is equal to the end portion temperature T₀. With reference to the end portion temperature T₀ measured in this manner, the temperature difference ΔT can be obtained. Thus, by measuring the temperature T on the center line in each of the state that an electromagnetic wave is propagating and the state that no electromagnetic wave is propagating, and obtaining the temperature difference ΔT from a difference therebetween, the influence of dispersion in characteristics of the thermistors 208 is reduced at the same time, and the distribution of the temperature difference ΔT can be obtained more precisely.

When it is difficult to provide the heat medium channels 217, a temperature sensor such as a thermistor, a resistance temperature sensor, a diode, a transistor, a temperature measuring IC, a thermocouple, or the like for measuring the end portion temperature T₀ of the conductive member 202 may be provided separately. Further, when a current or voltage in proportion to the temperature difference ΔT is outputted directly using a Peltier element as a temperature sensor for measuring the temperature T on the center line instead of the thermistor 208, a standing wave measuring apparatus having a simpler structure can be made.

To precisely obtain the maximal value ΔTₘₐₓ, the minimal value ΔTₘᵢₙ, and a position for taking the minimal value ΔTₘᵢₙ of the temperature difference ΔT, data of ΔT which are sequential with respect to the waveguide longitudinal direction. However, in this embodiment, the position of each through hole 205 is a temperature measuring point for the conductive member 202, and the temperature measuring points are limited. Accordingly, by a personal computer connected to the measuring circuit 213, data of sequential ΔT are calculated by interpolation calculation using Fourier transform from discrete measurement data of ΔT. It is structured such that, from calculated sequential data of ΔT, there are precisely obtained ΔTₘₐₓ, ΔTₘᵢₙ and a position for taking ΔTₘᵢₙ, and from these values, the guide wavelength, frequency, standing wave ratio, propagation constant, attenuation constant, phase constant, propagation mode, incident power, reflection power, and transmitted power, as well as the reflection coefficient and impedance of the load are calculated automatically.

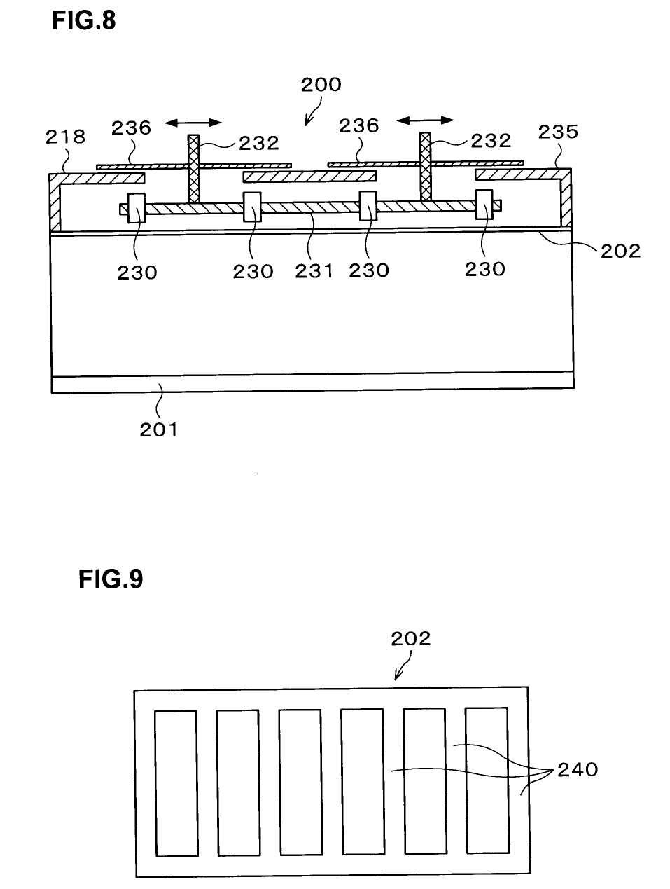

FIG. 8 is a vertical cross-sectional view of a rectangular waveguide 201 showing a second embodiment of a standing wave measuring unit 200 according to the present invention. An upper E face (narrow wall face) of the rectangular waveguide 201 is formed by a conductive member 202, and other faces (lower face and left and right side faces) are formed by metal walls 203. The conductive member 202 and the metal walls 203 are short-circuited electrically. The thickness of the conductive member 202 is 0.1 mm for example, and the material thereof is stainless steel for example. On an upper portion of the conductive member 202, four infrared sensors 230 as temperature sensors are disposed at even intervals on a center line of the conductive member 202. There is formed a 2 mm gap between the conductive member 202 and the infrared sensors 230. The infrared sensors 230 are coupled with each other by a coupling board 231. The coupling board 231 is provided with two support bars 232 and is held by the support bars 232. There is provided a mechanism (not shown) to reciprocate the support bars 232 in a waveguide longitudinal direction so as to enable reciprocating movement of the infrared sensors 230 together with the coupling board 231 in the waveguide longitudinal direction.

When an electric current flows in the conductive member 202 by energy of a microwave propagating in the rectangular waveguide 201, the conductive member 202 heats up according to the magnitude of the current, and the temperature increases. Infrared rays according to the temperature are emitted from a surface of the conductive member 202. By the infrared sensors 230 receiving the infrared rays and converting them into electrical signals, the temperature of the conductive member 202 is detected electrically. By performing temperature measurement while moving the plural infrared sensors 230 in the waveguide longitudinal direction, it is possible to measure a temperature distribution in the conductive member 202 with respect to a longitudinal direction of the rectangular waveguide 201. By the same method as in the first embodiment, the guide wavelength, frequency, standing wave ratio, propagation constant, attenuation constant, phase constant, propagation mode, incident power, reflection power, and transmitted power of an electromagnetic wave (microwave) propagating in the waveguide are obtained, and moreover the reflection coefficient and impedance of the load are obtained from the temperature distribution in the conductive member 202.

The space in which the infrared sensors 230 are provided is covered by a light shielding cover 235 and a support bar cover 236 so as to prevent entrance of infrared rays from the outside. On inner face of them, black coatings that absorb infrared rays are provided. Further, a black coating is provided also on a face (upper face) of the infrared sensor 230 side of the conductive member 202. By thus providing black coatings that absorb infrared rays, diffused reflection of the infrared rays can be prevented, and the temperature of the conductive member 202 can be measured more reliably. In addition, although the coatings are provided in this embodiment, the same effect can be obtained by applying black films or the like that absorb infrared rays.

Although four infrared sensors 230 are used in the embodiment shown in FIG. 8, a single sensor or plural sensors other than four may be used.

Note that although a plain plate is shown as the conductive member 202 in FIG. 1, FIG. 8, and so on, the conductive member 202 is not limited thereto. For example, as shown in FIG. 9, as the conductive member 202, a structure may be used in which conductive parts 240 extending in a direction orthogonal to the longitudinal direction of the rectangular waveguide 201 are disposed in parallel at predetermined even intervals. With such a structure in which the plural conductive parts 240 are disposed in parallel in the longitudinal direction of the rectangular waveguide 201, there is an advantage that respective temperatures of the conductive parts 240 can be detected precisely without allowing interference with each other in the longitudinal direction 220 of the rectangular waveguide 201.

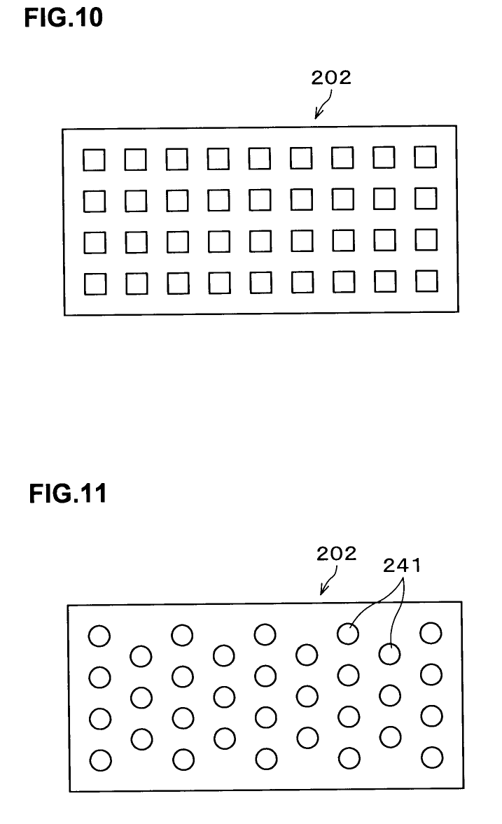

Further, for example, as the conductive member 202, there may be used a mesh structure as shown in FIG. 10 or a punching metal structure in which a large number of circular holes 241 are formed as shown in FIG. 11. Using the conductive member 202 having the mesh structure as shown in FIG. 10 or the punching metal structure as shown in FIG. 11, the electrical resistance becomes larger and the thermal conductivity becomes smaller than in the plain plate. Thus, it becomes possible to obtain a large temperature difference ΔT between the center line and the end portions of the conductive member 202 even when it has a relatively large thickness.

In the first and second embodiments, a stainless steel plate is used as the conductive member 202, but it may be a plate, a mesh, or the like of copper, aluminum, iron, brass, nickel, chrome, gold, silver, platinum, tungsten, or the like. Further, although the rectangular waveguide 201 is a simple straight pipe, a slot or the like may be formed in the H faces or E faces. Thus, it is possible to measure a guide wavelength, a propagation constant, a propagation mode, or the like in the rectangular waveguide 201 in the case where a slot or the like exists. Further, a temperature distribution in the conductive member 202 may be measured using an infrared camera.

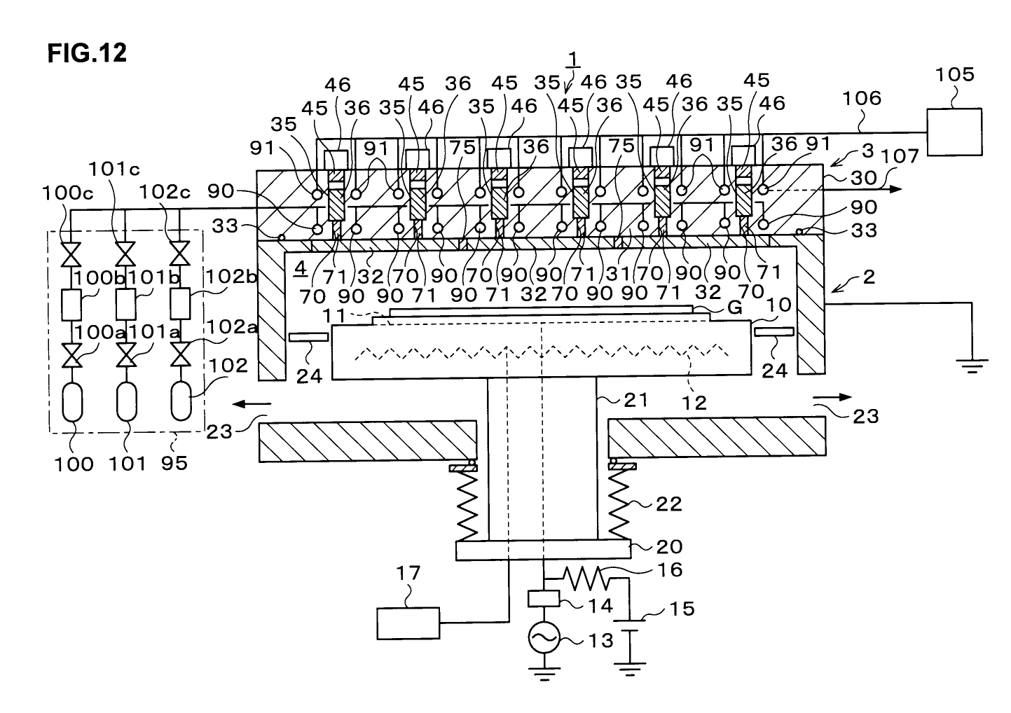

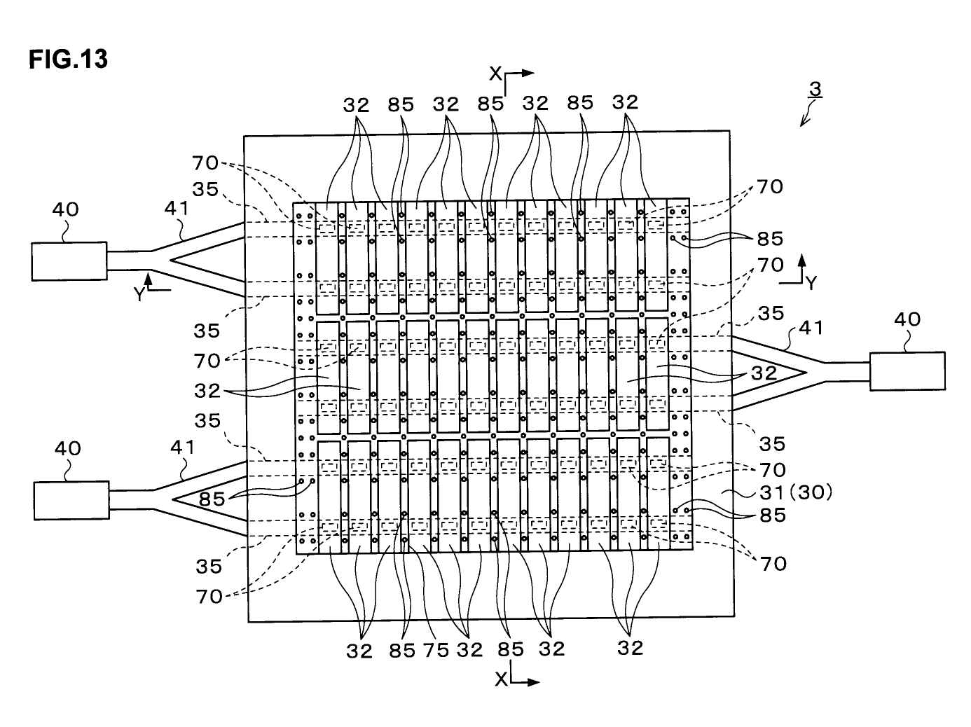

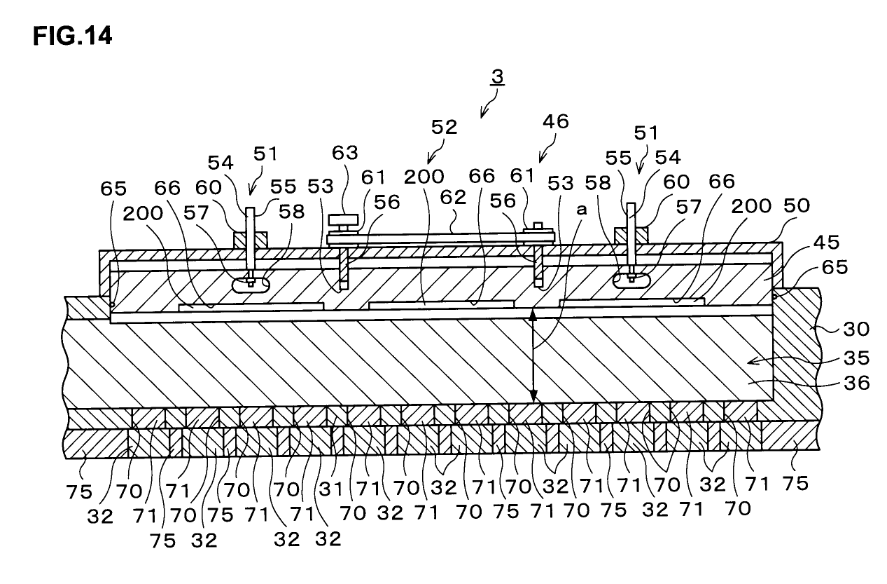

Next, an embodiment of the present invention will be explained based on a plasma processing apparatus 1 which performs CVD (chemical vapor deposition) processing as an example of plasma processing. FIG. 12 is a vertical cross-sectional view (X-X cross section in FIG. 13) showing a schematic structure of the plasma processing apparatus 1 according to the embodiment of the present invention. FIG. 13 is a bottom view of a lid 3 included in this plasma processing apparatus 1. FIG. 14 is a partially enlarged vertical cross-sectional view (Y-Y cross-section in FIG. 13) of the lid 3.

This plasma processing apparatus 1 includes a processing vessel 2 in a bottomed cubic shape with an open upper portion and a lid 3 covering an upper side of this processing vessel 2. A processing chamber 4 that is a sealed space is formed inside the processing vessel 2 by covering the upper side of the processing vessel 2 with the lid 3. These processing vessel 2 and lid 3 are formed of a non-magnetic material having conductivity, aluminum for example, and are both in an electrically grounded state.

In the processing chamber 4, a susceptor 10 as a mounting table for mounting, for example, a glass substrate (hereinafter referred to as “substrate”) G as a substrate is provided. This susceptor 10 is made of an aluminum nitride for example, and in the inside thereof, there are provided a power feeding unit 11 for electrostatically attracting the substrate G and applying a predetermined bias voltage to the inside of the processing chamber 4, and a heater 12 for heating the substrate G to a predetermined temperature. To the power feeding unit 11, a radio-frequency power supply 13 for applying bias provided outside the processing chamber 4 is connected via a matching device 14 including a capacitor and the like, and a high-voltage DC power supply 15 for electrostatic attraction is connected via a coil 16. An AC power supply 17 provided outside the processing chamber 4 is connected similarly to the heater 12.

The susceptor 10 is supported via a cylinder 21 on a lift plate 20 provided outside and below the processing chamber 4, and is integrally moved up and down with the lift plate 20 so as to adjust the height of the susceptor 10 in the processing chamber 4. However, a bellows 22 is attached between a bottom face of the processing vessel 2 and the lift plate 20, and thus the airtightness in the processing chamber 4 is maintained.

In a bottom portion of the processing vessel 2, an exhaust port 23 is provided for exhausting the atmosphere in the processing chamber 4 by an exhaust device (not shown) such as a vacuum pump provided outside the processing chamber 4. Further, around the susceptor 10 in the processing chamber 4, a current plate 24 is provided for controlling a flow of gas in the processing chamber 4 in a preferable condition.

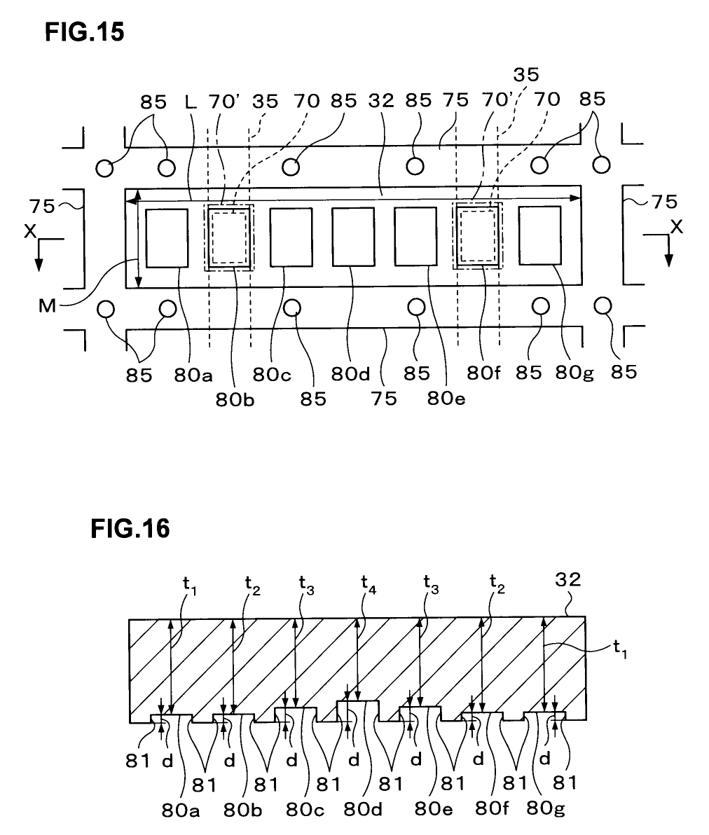

The lid 3 has a structure such that a slot antenna 31 is formed integrally on a lower face of a lid body 30, and further, plural dielectrics 32 in tile forms are attached on a lower face of the slot antenna 31. The lid body 30 and the slot antenna 31 are formed integrally by a conductive material, such as aluminum for example, and are in electrically grounded states. As shown in FIG. 12, in a state that the upper side of the processing vessel 2 is closed by the lid 3, the airtightness in the processing chamber 4 is maintained by an O-ring 33 disposed between a peripheral portion of the lower face of the lid body 30 and an upper face of the processing vessel 2 and O-rings (arrangement positions of the O-rings are shown by chain-dashed lines 70′ in FIG. 15) disposed respectively around slots 70, which will be described later.

Inside the lid body 30, plural rectangular waveguides 35 having rectangular cross sections are disposed horizontally. In this embodiment, six rectangular waveguides 35 each extending on a straight line are included, and the rectangular waveguides 35 are disposed side by side to be in parallel with each other. In this arrangement, a long side direction (side wall face) of a cross-sectional shape (rectangular) of each rectangular waveguide 35 is vertical as an H face, and a short side direction (narrow wall face) thereof is horizontal as an E face. Incidentally, the way of arranging the long side direction and the short side direction varies depending on the mode. Further, the inside of each rectangular waveguide 35 is filled with a dielectric member 36, fluorine resin for example (Teflon (registered trademark) for example). In addition, as the material of the dielectric member 36, a dielectric material such as Al₂O₃ or quartz for example can be used besides the fluorine resin.

As shown in FIG. 13, three microwave supply devices (power supplies) 40 are provided outside the processing chamber 4 in this embodiment, and from each of the microwave supply devices 40, microwaves of 2.45 GHz for example are introduced into two of the rectangular waveguides 35 provided in the lid body 30. Between each of the microwave supply devices 40 and two of the rectangular waveguides 35, a Y branch pipe 41 is connected for dividing and introducing a microwave into the two rectangular waveguides 35.

As shown in FIG. 12, an upper portion of each rectangular waveguide 35 formed in the lid body 30 is opened in an upper face of the lid body 30, and from an upper side of each rectangular waveguide 35 opened as such, an upper face member 45 is inserted in each rectangular waveguide 35 to be movable up and down. This upper face member 45 is also formed by a non-magnetic material having conductivity, aluminum for example.

On the other hand, a lower face of each rectangular waveguide 35 formed in the lid body 30 constitutes a slot antenna 31 formed integrally on the lower face of the lid body 30. As described above, since the short side direction of an inner face of each rectangular waveguide 35 formed to have a rectangular cross-sectional shape is an E face, a lower face of the upper face member 45 facing the inside of the rectangular waveguide 35 and an upper face of the slot antenna 31 are E faces. On an upper side of the lid body 30, a lift mechanism 46 is provided for each rectangular waveguide 35 so as to move the upper face member 45 of the rectangular waveguide 35 up and down with respect to the lower face (slot antenna 31) of the rectangular waveguide 35 while keeping its horizontal posture.

As shown in FIG. 14, the upper face member 45 of the rectangular waveguide 35 is disposed in a cover 50 attached covering the upper face of the lid body 30. Inside the cover 50, a space is formed with an adequate height for moving up and down the upper face member 45 of the rectangular waveguide 35. On an upper face of the cover 50, a pair of guide units 51 and a lift unit 52 arranged between the guide units 51 are disposed, and these guide units 51 and lift unit 52 form the lift mechanism 46 which moves up and down the upper face member 45 of the rectangular waveguide 35 while keeping its horizontal posture.

The upper face member 45 of the rectangular waveguide 35 is suspended from the upper face of the cover 50 via a pair of guide rods 55 provided respectively in the guide units 51 and a pair of lift rods 56 provided in the lift unit 52. The lift rods 56 are formed by screws, and by screw-engaging (screwing) lower ends of the lift rods 56 with screw holes 53 formed in an upper face of the upper face member 45, the upper face member 45 of the rectangular waveguide 35 is supported in the cover 50 without allowing it to fall.

Nuts 57 for stoppers are attached on lower ends of the guide rods 55, and these nuts 57 are fastened and fixed in holes 58 formed inside the upper face member 45 of the rectangular waveguide 35 to thereby fix the pair of guide rods 55 vertically in the upper face of the upper face member 45.

Upper ends of the guide rods 55 and the lift rods 56 penetrate an upper face of the cover 50 and project upward. The upper ends of the guide rods 55 projecting on the guide units 51 penetrate guides 60 fixed on the upper face of the cover 50, and the guide rods 55 are allowed to slide in a vertical direction in the guides 60. By the guide rods 55 which slide in the vertical direction in this manner, the upper face member 45 of the rectangular waveguide 35 is always kept in a horizontal posture, and the E faces (the upper face member 45 and the lower face (the upper face of the slot antenna 31)) of the rectangular waveguide 35 are always in parallel.

On the other hand, timing pulleys 61 are fixed on the upper ends of the lift rods 56 projecting on the lift unit 52. These timing pulleys 61 are mounted on the upper face of the cover 50 to thereby support the upper face member 45 screw-engaged (screwed) with the lower ends of the lift rods 56 in the cover 50 without allowing to fall.

The timing pulleys 61 attached to the pair of lift rods 56 are structured to rotate synchronously with each other by a timing belt 62. Further, a rotation handle 63 is attached on an upper end of the lift rods 56. By rotary operating this rotation handle 63, the pair of lift rods 56 are rotated synchronously via the timing pulleys 61 and the timing belt 62, and thereby the upper face member 45 fixed by screwing (screwed) on the lower ends of the lift rods 56 is moved up and down in the cover 50.

In the lift mechanism 46 as such, by rotary operating the rotation handle 63, the upper face member 45 of the rectangular waveguide 35 can be moved up and down in the cover 50, and while moving, the guide rods 55 provided in the guide units 51 slide in the vertical direction in the guides 60, the upper face member 45 of the rectangular waveguide 35 is constantly kept in a horizontal posture, and the E faces (the upper face member 45 and the lower face of the rectangular waveguide 35 (the upper face of the slot antenna 31)) are always in parallel.

As described above, since the dielectric member 36 is filled in the rectangular waveguide 35, the upper face member 45 of the rectangular waveguide 35 is able to move down to a position in contact with the upper face of the dielectric member 36. Then, by thus moving the upper face member 45 of the rectangular waveguide 35 up and down in the cover 50 with the position in contact with the upper face of the dielectric member 36 being a lower limit, the width a between the E faces (height of the upper face (lower face of the upper face member 45) of the rectangular waveguide 35 with respect to the lower face (upper face of the slot antenna 31) of the rectangular waveguide 35) can be changed arbitrarily. In addition, the height of the cover 50 is set so that the upper face member 45 can be moved to an adequate height when the upper face member 45 of the rectangular waveguide 35 is moved up and down according to the condition of plasma processing performed in the processing chamber 4 as will be described later.

The upper face member 45 is formed by a conductive non-magnetic material such as aluminum for example, and on a peripheral face portion of the upper face member 45, a shield spiral 65 for electrical conduction to the lid body 30 is attached. On the surface of this shield spiral 65, for example a gold plate or the like for reducing the electrical resistance is provided. Therefore, the entire inner wall face of the rectangular waveguide 35 is formed by conductive members which are electrically conducting with each other, and is structured so that an electrical current flows smoothly without discharging along the entire inner wall surface of the rectangular waveguide 35.

On the upper face member 45, standing wave measuring units 200 for measuring the distribution of a standing wave generated in the rectangular waveguide 35 are attached at three positions. In the upper face member 45, there are formed recesses 66 for inserting these standing wave measuring units 200, and with the standing wave measuring units 200 being disposed in the recesses 66 respectively, lower faces of the standing wave measuring units 200 (conductive member 202) are set at approximately the same height as the lower face of the upper face member 45.

A standing wave measuring unit 200 has the structure explained previously with FIG. 1 to FIG. 11, in which a conductive member 202 is disposed along the longitudinal direction of the rectangular waveguide 35 so as to form at least one portion of the E faces of the rectangular waveguide 35, and has a temperature variation detecting means for detecting a temperature variation of the conductive member 202 with respect to the longitudinal direction of the rectangular waveguide 35 outside the rectangular waveguide 35. The temperature variation detecting means is able to obtain the interval between adjacent nodes or antinodes of a standing wave and further to measure the guide wavelength λg by detecting a temperature variation of the conductive member 202 with respect to the longitudinal direction of the rectangular waveguide 35 by the plural thermistors 208 disposed along the longitudinal direction of the rectangular waveguide 35 for example.

As shown in FIG. 12, in the lower face of each rectangular waveguide 35 forming the slot antenna 31, plural slots 70 as through holes are disposed at even intervals along the longitudinal direction of each rectangular waveguide 35. In this embodiment, 12 slots 70 (corresponding to G5) are disposed in series in each rectangular waveguide 35, and 12×6 columns=72 slots are disposed in the entire slot antenna 31 by an equal distribution in the entire lower face (slot antenna 31) of the lid body 30. The intervals between the slots 70 are set such that an interval between slots 70 adjacent to each other, from a center axis to a center axis, is λg′/2 for example (λg′ is a waveguide wavelength of a microwave in initial setting for 2.45 GHz) in the longitudinal direction of each rectangular waveguide 35. Note that the number of slots 70 formed in each rectangular waveguide 35 is arbitrary, and in the entire slot antenna 31, for example 13 slots 70 may be provided in each rectangular waveguide 35 to thereby distribute 13×6 columns=78 slots 70 evenly in the entire lower face (slot antenna 31) of the lid body 30.

In each of the slots 70 thus disposed by an even distribution in the entire slot antenna 31, a dielectric member 71 formed by Al₂O₃ for example is filled. In addition, as the dielectric member 71, a dielectric material such as fluorine resin or quartz for example can also be used. Further, under these slots 70, plural dielectrics 32 are disposed respectively, which are attached to the lower face of the slot antenna 31 as described above. Each dielectric 32 forms a rectangular plate shape and is formed by a dielectric material such as quartz glass, AlN, Al₂O₃, sapphire, SiN, or ceramics for example.

As shown in FIG. 13, each dielectric 32 is disposed across two rectangular waveguides 35 connected via a Y branch pipe 41 for one microwave supply device 40. As described above, a total of six rectangular waveguides 35 are disposed in parallel in the lid body 30, and the dielectrics 32 are disposed in three columns each corresponding to two of the rectangular waveguides 35.

Further, as described above, 12 slots 70 are disposed in series on the lower face (slot antenna 31) of each rectangular waveguide 35, and the dielectrics 32 are each attached across respective slots 70 of two rectangular waveguides 35 (two rectangular waveguides 35 connected to the same microwave supply device 40 via a Y branch pipe 41) adjacent to each other. Accordingly, a total of 12×3 columns=36 dielectrics 32 are attached on the lower face of the slot antenna 31. On the lower face of the slot antenna 31, a beam 75 formed in a lattice shape is provided for supporting these 36 dielectrics 32 in a state of being disposed in 12×3 columns. Note that the number of slots 70 formed in the lower face of each rectangular waveguide 35 is arbitrary, and for example 13 slots 70 may be provided in the lower face of each rectangular waveguide 35 to thereby dispose 13×3 columns=39 dielectrics 32 in total in the lower face of the slot antenna 31.

Here, FIG. 15 is an enlarged view of a dielectric 32 seen from the lower side of the lid 3. FIG. 16 is a cross section of the dielectric 32 taken along a line X-X in FIG. 15. The beam 75 is disposed so as to surround peripheries of the dielectrics 32, and supports the dielectrics 32 in a state of being appressed to the lower face of the slot antenna 31. The beam 75 is formed of a non-magnetic conductive material such as aluminum for example, and in a state of being grounded electrically together with the slot antenna 31 and the lid body 30. This beam 75 supporting peripheries of the dielectrics 32 makes a state that a large part of the lower faces of the dielectrics 32 is exposed in the processing chamber 4.

The gaps between the dielectrics 32 and the slots 70 are in a sealed state using seal members such as O-rings 70′. Microwaves are introduced under atmospheric pressure for example into the rectangular waveguides 35 formed in the lid body 30, but the airtightness in the processing chamber 4 is maintained since the gaps between the dielectrics 32 and the slots 70 respectively are sealed in this manner.

Each dielectric 32 is formed in a rectangular shape having a length L in a longitudinal direction longer than the free space wavelength λ=approximately 120 mm of a microwave in the evacuated processing chamber 4 and a length M in a width direction shorter than the free space wavelength λ. When microwaves of 2.54 GHz for example are generated by the microwave supply device 40, the wavelength λ of microwaves propagating surfaces of the dielectrics becomes approximately equal to the free space wavelength λ. Thus, the length L in the longitudinal direction of each dielectric 32 is set longer than 120 mm, for example to 188 mm. Further, the length M in the width direction of each dielectric 32 is set shorter than 120 mm, for example to 40 mm.

Further, projections and recesses are formed in the lower face of each dielectric 32. Specifically, in this embodiment, seven recesses 80a, 80b, 80c, 80d, 80e, 80f, 80g are disposed in series in the lower face of each dielectric 32 formed in a rectangular shape along a longitudinal direction thereof. The recesses 80a to 80g are each formed in an approximately identical, substantially rectangular shape in plan view. Further, an inside face of each of the recesses 80a to 80g is a substantially vertical wall face 81.

Not all of the recesses 80a to 80g have the same depths d, and a part or all of the recesses 80a to 80g are formed to have different depths d. In the embodiment shown in FIG. 7, the depths d of the recesses 80b, 80f which are closest to the slots 70 are smallest, and the depth d of the recess 80d which is farthest from the slots 70 is largest. Then the recesses 80a, 80c and recesses 80e, 80g located respectively on both sides of the recesses 80b, 80f right below the slots 70 have depths d which are intermediate between the depths d of the recesses 80b, 80f right below the slots 70 and the depth d of the recess 80d that is farthest from the slots 70.

However, for the recesses 80a, 80g located on both ends in a longitudinal direction of the dielectric 32 and the recesses 80c, 80e located inside the two slots 70, the depths d of the recesses 80a, 80g on the both ends are smaller than the depths d of the recesses 80c, 80e located inside the slots 70. Therefore, in this embodiment, the relationship of the depths d of the recesses 80a to 80g is such that depths d of the recesses 80b, 80f closest to the slots 70<depths d of the recesses 80a, 80g located on the both ends in the longitudinal direction of the dielectric 32<depths d of the recesses 80c, 80e located inside the slots 70<depth d of the recess 80d farthest from the slot 70.

Further, a thicknesses t₁ of the dielectric 32 at the positions of the recess 80a and the recess 80g, a thicknesses t₂ of the dielectric 32 at the positions of the recess 80b and the recess 80f, and a thicknesses t₃ of the dielectric 32 at the positions of the recess 80c and the recess 80e are all set to thicknesses which do not practically hinder propagation of a microwave at the positions of the recesses 80a to 80c and propagation of a microwave at the positions of the recesses 80e to 80g respectively when a microwave propagates in the dielectric 32 as will be described later. On the other hand, a thickness t₄ of the dielectric 32 at the position of the recess 80d is set to a thickness which generates what is called cut-off at the position of the recess 80d and which practically does not allow propagation of a microwave at the position of the recess 80d when a microwave propagates in the dielectric 32 as will be explained later. Accordingly, propagation of a microwave at the positions of the recesses 80a to 80c disposed on the side of the slot 70 of one rectangular waveguide 35 and propagation of a microwave at the positions of the recesses 80e to 80g disposed on the side of the slot 70 of the other rectangular waveguide 35 are cut off at the position of the recess 80d and do not interfere with each other, thereby preventing interference between a microwave exiting the slot 70 of one rectangular waveguide 35 and a microwave exiting the slot 70 of the other rectangular waveguide 35.

In a lower face of the beam 75 supporting the dielectrics 32, gas injection ports 85 for supplying a predetermined gas into the processing chamber 4 are provided in surrounding areas of the dielectrics 22 respectively. The gas injection ports 85 are formed at plural positions so as to surround each of the dielectrics 22, and thereby the gas injection ports 85 are disposed by an even distribution in the entire upper face of the processing chamber 4.

As shown in FIG. 12, gas pipes 90 for supplying a predetermined gas and cooling water pipes 91 for supplying cooling water are provided in the lid body 30. The gas pipes 90 communicate with the respective gas injection ports 85 provided in the lower face of the beam 75.

A predetermined gas supply source 95 disposed outside the processing chamber 4 is connected to the gas pipes 90. In this embodiment, as the predetermined gas supply source 95, there are prepared an argon gas supply source 100, a silane gas supply source 101 as a film forming gas and a hydrogen gas supply source 102, which are connected to the gas pipes 90 via valves 100a, 101a, 102a, mass flow controllers 100b, 101b, 102b, and valves 100c, 101c, 102c, respectively. Accordingly, a predetermined gas supplied from the predetermined gas supply source 95 to the gas pipes 90 are injected into the processing chamber 4 via the gas injection ports 85.

A cooling water supply pipe 106 supplying cooling water in a circulated manner from a cooling water supply source 105 disposed outside the processing chamber 4 and a cooling water return pipe 107 are connected to the cooling water pipes 91. The cooling water is supplied in a circulated manner from the cooling water supply source 105 to the cooling water pipes 91 via these cooling water supply pipe 106 and cooling water return pipe 107 so as to keep the lid body 30 at a predetermined temperature.

Now, the case where an amorphous silicon film for example is formed in the plasma processing apparatus 1 according to the embodiment of the present invention structured as above will be explained. When processing, a substrate G is mounted on the susceptor 10 in the processing chamber 4, and the inside of the processing chamber 4 is set to a predetermined pressure by exhausting via the exhaust port 23 while a predetermined gas, for example a mixed gas of argon gas, silane gas, and hydrogen is supplied into the processing chamber 4 via the gas pipes 90 and the gas injection ports 85 from the predetermined gas supply source 95. In this case, by injecting the predetermined gas via the gas injection ports 85 disposed by distributing in the entire lower face of the lid body 30, the predetermined gas can be supplied evenly onto the entire surface of the substrate G mounted on the susceptor 10.

Then, while the predetermined gas is thus supplied into the processing chamber 4, the substrate G is heated to a predetermined temperature by the heater 12. Further, microwaves of 2.45 GHz for example generated by the microwave supply devices 40 shown in FIG. 2 are introduced into the rectangular waveguides 35 via the Y branch pipes 41 and propagate in the dielectrics 32 via the respective slots 70.

Here, in each rectangular waveguide 35, a standing wave is generated by interference of an incident wave of a microwave introduced from the microwave supply device 40 with a reflection wave, and electric fields E and magnetic fields H as explained previously with FIG. 4 are formed. Then, in the upper face and the lower face of the rectangular waveguide 35 which are E faces (the lower face of the upper face member 45 and the upper face of the slot antenna 31), E-face currents I flow in directions orthogonal to the longitudinal direction 220 of the rectangular waveguide 35 (that is, width directions of the upper face and the lower face of the rectangular waveguides 35). Then, the E-face currents I thus flowing in the upper face and the lower face of the rectangular waveguide 35 change by sine wave periods with the same amplitude as the guide wavelength λg in the longitudinal direction 220 of the rectangular waveguide 35, and exhibit a positive maximum value and a negative maximum value repeatedly at intervals of the length λg/2, which is half the guide wavelength λg.

Thus, periods of the E-face currents I flowing in the upper face and the lower face of the rectangular waveguide 35 in the longitudinal direction 35′ of the rectangular waveguide 35 and the guide wavelength λg always match, and they are in a relationship such that when the guide wavelength λg changes, the periods of the E-face currents I flowing in the upper face and the lower face of the rectangular waveguide 35 in the longitudinal direction 35′ of the rectangular waveguide 35 change similarly.

Specifically, by energy of a microwave propagating in the rectangular waveguide 35, E-face currents I flowing in the width directions on the upper face and the lower face of the rectangular waveguide 35 repeat a maximum value in a positive direction (one width direction) and a maximum value in a negative direction (the other width direction) by periods of the interval λg/2, which is half the guide wavelength λg as shown in FIG. 6. Further, in the rectangular waveguide 35, a standing wave generated by the energy of a microwave similarly repeats to be weak and strong by periods of the interval λg/2.

On the other hand, by the E-face currents I thus flowing alternately in the positive and negative directions by periods of the interval λg/2, which is half the guide wavelength λg, on the upper face (lower face of the upper face member 45) of the rectangular waveguide 35 by energy of a microwave introduced from the microwave supply device 40 in this manner, the conductive members 202 provided on the standing wave measuring units 200 heat up according to the magnitude of the E-face currents I. In this case, the magnitude of the E-face currents I flowing through the conductive members 202 repeats to be weak and strong by periods of the interval λg/2 in the longitudinal direction of the conductive members 202 (longitudinal direction of the rectangular waveguide 35), and thus the temperature distribution in the conductive members 202 is such that the temperature becomes high and low repeatedly by periods of the interval λg/2 in the longitudinal direction of the rectangular waveguide 35.

On the other hand, in the standing wave measuring units 200, by the plural thermistors 208 explained previously with FIGS. 1 to 3 for example, temperatures of the conductive members 202 are detected at respective positions in the longitudinal direction of the rectangular waveguide 35. The temperatures of the conductive members 202 at respective positions in the longitudinal direction of the rectangular waveguide 35 which are thus detected by the thermistors 208 are inputted to the measuring circuit 214 via the cable 213, and a temperature distribution in the conductive members 202 with respect to the longitudinal direction of the rectangular waveguide 35 is measured.

The temperature distribution in the conductive members 202 with respect to the longitudinal direction of the rectangular waveguide 35 detected by the measuring circuit 214 in this manner becomes equal to changes of the magnitude of the E-face currents I flowing through respective positions in the conductive members 202, and at a position where a maximal value of temperature is exhibited, it means that the E-face current I of positive maximum value or negative maximum value has flown in the conductive members 202. Thus, with the measuring circuit 214 of the standing wave measuring unit 200, it becomes possible to measure periods of a standing wave in the longitudinal direction 220 of the rectangular waveguide 35 (that is, the interval λg/2 which is half the guide wavelength λg). Then, it is possible to precisely measure from periods of the thus detected standing wave the wavelength (guide wavelength) λg of an actual microwave that propagates in the rectangular waveguide 35.

In addition, when a microwave introduced into the rectangular waveguide 35 is propagated to the dielectrics 32 via the slots 70, it is possible to securely propagate a microwave introduced into the rectangular waveguide 35 to the dielectrics 32 via the slots 70 since the dielectric members 71 with higher permittivity than air, such as fluorine resin, Al₂O₃, or quartz for example, are filled in the slots 70.

Thus, by energy of the microwave propagated in the dielectrics 32, electromagnetic fields are formed in the processing chamber 4 on surfaces of the dielectrics 32, and the aforementioned processing gas in the processing vessel 2 is turned into plasma by electric field energy, to thereby perform formation of an amorphous silicon film on the surface of the substrate G. In this case, since the recesses 80a to 80g are formed in the lower face of each dielectric 32, substantially vertical electric fields on the inner side faces (wall faces 81) of these recesses 80a to 80g are formed by energy of the microwave propagated in the dielectrics 32, and in the vicinities thereof the plasma can be generated efficiently. Further, the generation position of the plasma can be stabilized. Furthermore, since the depths d of the plural recesses 80a to 80g formed in the lower face of each dielectric 32 are made different from each other, the plasma can be generated almost evenly on the entire lower face of each dielectric 32. Further, since the width of the dielectric 32 is 40 mm for example, which is narrower than the free space wavelength λ=approximately 120 mm of a microwave, and the length in the longitudinal direction of the dielectric 32 is 188 mm for example, which is longer than the free space wavelength λ guide wavelength λg of a microwave, a surface wave can be propagated only in the longitudinal direction of the dielectrics 32. Moreover, by the recess 80d provided in the middle of each dielectric 32, interference of microwaves with each other propagated from two slots 70 is prevented.

Note that in the processing chamber 4, even film formation causing low damage to the substrate G is performed, for example, at a low electron temperature of 0.7 eV to 2.0 eV and with high density plasma of 10¹¹ cm⁻³ to 10¹³ cm⁻³. As the condition of amorphous silicon film formation, for example 5 Pa to 100 Pa, preferably 10 Pa to 60 Pa is suitable for the pressure in the processing chamber 4, and 200° C. to 450° C., preferably 250° C. to 380° C. is suitable for the temperature of the substrate G. Further, as the size of the processing chamber 4, G3 or larger (G3 refers to dimensions of the substrate G: 400 mm×500 mm, internal dimensions of the processing chamber 4: 720 mm×720 mm) is suitable, for example G4.5 (dimensions of the substrate G: 730 mm×920 mm, internal dimensions of the processing chamber 4: 1000 mm×1190 mm), G5 (dimensions of the substrate G: 1100 mm×1300 mm, internal dimensions of the processing chamber 4: 1470 mm×1590 mm), and as output of power of the microwave supply device, 1 W/cm² to 4 W/cm², preferably 3 W/cm² is suitable. When the output of power of the microwave supply device is 1 W/cm² or higher, plasma ignites, and this allows relatively stable generation of plasma. When the output of power of the microwave supply device is lower than 1 W/cm², the plasma does not ignite, or generation of plasma becomes quite unstable, which makes the process unstable, uneven and hence impractical.

Here, such conditions of plasma processing (for example, gas type, pressure, power output of the microwave supply device, and the like) performed in the processing chamber 4 are set appropriately depending on the type of processing or the like, but on the other hand, when the impedance in the processing chamber 4 for plasma generation changes by changing the conditions of plasma processing, there is a nature that the wavelength (guide wavelength λg) of a microwave propagating in each rectangular waveguide 35 changes accompanying this change. Further, on the other hand, since the slots 70 are provided at the predetermined intervals (λg′/2) for each rectangular waveguide 35 as described above, when the impedance varies by the conditions of plasma processing and thereby the guide wavelength λg changes, the interval (λg′/2) between the slots 70 and the interval between antinode portions of a standing wave (distance (λg/2) that is half the guide wavelength λg) no longer match. As a result, the antinode portions of a standing wave no longer match with the plural slots 70 arranged along the longitudinal direction of each rectangular waveguide 35, and this makes it not possible to propagate a microwave efficiently in the dielectrics 32 on the upper face of the processing chamber 4 from the respective slots 70.

However, in the embodiments of the present invention, in the standing wave measuring units 200 attached to an upper face member 45 as described above, the measuring circuit 214 obtains the period λg/2 of a standing wave in the longitudinal direction 220 of the rectangular waveguide 35 based on a temperature variation in the conductive members 202 which is electrically detected by the respective thermistors 208, and the wavelength (guide wavelength) kg of an actual microwave propagating in the rectangular waveguide 35 is measured precisely. Then, the measuring circuit 214 is able to immediately detect a situation that the interval (λg′/2) between the slots 70 and the interval between antinode portions of a standing wave no longer match by comparing the thus measured period λg/2 of a standing wave with the interval (λg′/2) between the slots 70.

Further, in the embodiments of the present invention, when such a situation that the interval (λg′/2) between the slots 70 and the interval between antinode portions of a standing wave no longer match is detected, it is possible to move the upper face member 45 of E each rectangular waveguide 35 up and down with respect to the lower face (upper face of the slot antenna 31) so as to adjust the guide wavelength λg, thereby matching the antinode portions of the standing wave to the respective slots 70.

In addition, moving up and down the upper face member 45 can be performed easily by rotary operating the rotation handle 63 of the lift mechanism 46. For example, when the guide wavelength λg becomes shorter due to plasma processing condition in the processing chamber 4, the upper face member 45 of the rectangular waveguide 35 is moved down in the cover 50 by rotary operating the rotation handle 63 of the lift mechanism 46. Thus, when the interval a between the E faces (height of the upper face member 45 with respect to the lower face of the rectangular waveguide 35) is reduced, the guide wavelength λg changes to be longer. Conversely, when the guide wavelength λg becomes longer due to plasma processing condition in the processing chamber 4, the upper face member 45 of the rectangular waveguide 35 is moved up in the cover 50 by rotary operating the rotation handle 63 of the lift mechanism 46. Thus, when the interval a between the E faces (height of the upper face member 45 with respect to the lower face of the rectangular waveguide 35) is enlarged, the guide wavelength λg changes to be shorter. By appropriately changing the interval a between the E faces, the interval (λg/2) between antinode portions of a standing wave and the interval (λg′/2) between the slots can be matched. As a result, a microwave can be propagated efficiently from the plural slots 70 formed in the lower face of the rectangular waveguide 35 to the dielectrics 32 in the upper face of the processing chamber 4, which allows to form an even electromagnetic field on the entire upper side of the substrate G, and makes it possible to perform even plasma processing on the entire surface of the substrate G. Changing the guide wavelength λg of a microwave makes it unnecessary to change the intervals between the slots 70 for every condition of the plasma processing, equipment costs thereof can be reduced, and it further becomes possible to sequentially perform different type of plasma processing in the same processing chamber 4. Note that the operation of moving up and down the upper face member 45 depending on the period of a standing wave detected in this manner may be performed manually, but a control unit for automatically moving up and down the upper face member 45 by a publicly known automatic control method depending on a change of the period of a standing wave may be provided to perform this operation.

In addition, with the plasma processing apparatus 1 of this embodiment, since the plural dielectrics 32 in tile forms are attached to the upper face of the processing chamber 4, the dielectrics 32 can be reduced in size and weight. Accordingly, manufacturing the plasma processing apparatus 1 also becomes simple and at low cost, which can improve capability in responding to area enlargement of the substrate G. Further, the slots 70 are provided in each dielectric 32, the area of each dielectric 32 is significantly small, and the recesses 80a to 80g are formed in the lower face thereof. Thus, a microwave can be propagated evenly into each dielectric 32, and plasma can be generated efficiently by the entire lower face of each dielectric 32. Accordingly, even plasma processing can be performed in the entire processing chamber 4. Further, the beam 75 (support member) supporting the dielectrics 32 can be made thin, so a large part of the lower face of each dielectric 32 is exposed in the processing chamber 4. Thus, the beam 75 barely becomes an obstacle when an electromagnetic field is formed in the processing chamber 4, and an even electromagnetic field can be formed on the entire upper side of the substrate G, thereby enabling generation of even plasma in the processing chamber 4.

Further, gas injection ports 85 for supplying a processing gas may be provided in the beam 75 supporting the dielectrics 32 as in the plasma processing apparatus 1 of this embodiment. Moreover, as explained in this embodiment, when the beam 75 is formed by metal such as aluminum for example, processing of the gas injection ports 85 and so on becomes easy.

In the foregoing, examples of preferred embodiments of the present invention have been explained, but the present invention is not limited to the embodiments shown herein. The above explanation is given assuming that half (λg/2) the guide wavelength λg and the period of a standing wave are equal, but as explained previously, in the plasma processing apparatus 1, the period of a standing wave and half (λg/2) the guide wavelength λg no longer match in the strict sense due to the influence of microwaves propagating in the processing chamber 4 via the slots 70, the influence of reflection waves entering the rectangular waveguides 35 from the processing chamber 4 via the slots 70, and the like. However, the period of a standing wave is almost equal to half λg/2 the guide wavelength λg, which is the wavelength of a microwave propagating in a waveguide, and can be a measure of the guide wavelength λg. Therefore, when it can be assumed that the period of a standing wave is substantially equal to half (λg/2) the guide wavelength λg, it becomes possible to propagate a microwave efficiently to the dielectrics 32 from the respective slots 70 on the lower face of the rectangular waveguide 35 by controlling the guide wavelength λg according to the above assumption. On the other hand, when it cannot be assumed that the period of a standing wave is substantially equal to half (λg/2) the guide wavelength λg, checking a relationship between the period of a standing wave and the guide wavelength kg in advance makes it possible to control the guide wavelength λg with the period of a standing wave similarly being a measure.

Further, for example, the thermistor 208 is shown as an example of the temperature sensor, but besides this, a temperature sensor such as a resistance temperature sensor, a thermocouple, a thermolabel, or the like may be used. Further, for example, a temperature may be measured indirectly by arranging plural infrared sensors and measuring infrared rays emitted from a waveguide. Moreover, for example, a temperature distribution may be measured indirectly by moving an infrared sensor along the longitudinal direction of a waveguide. Furthermore, an infrared camera such as a thermoviewer may be used to measure a temperature indirectly.

Further, in the foregoing, the period of a standing wave is measured based on a temperature distribution in the conductive members 202 with respect to the waveguide longitudinal direction, but as explained with FIG. 4, the E-face currents I which is vertical to the waveguide longitudinal direction 220 flow inside the E faces (narrow wall faces) in the rectangular waveguide 201, and the E-face currents I become 0 at a position where the electric fields E is maximum but conversely the E-face currents I become maximum at a position where the electric fields E are 0. Accordingly, it is also possible to detect a current flowing vertically with respect to the waveguide longitudinal direction in the conductive members 202 and measure a standing wave based on a distribution of currents with respect to the waveguide longitudinal direction.

In addition, as in the embodiment of the illustrated plasma processing apparatus 1, with an arrangement such that the long side directions of the cross section (rectangular) of the rectangular waveguide 35 are vertical as the H faces and the short side directions are horizontal as the E faces, a gap between rectangular waveguides 35 can be made wide. Thus, for example, the gas pipes 90 or the cooling water pipes 91 can be disposed easily, and the number of rectangular waveguides 35 can be increased further.

In the above embodiments, one performing amorphous silicon film formation as an example of plasma processing is explained. However, besides the amorphous silicon film formation, the present invention can be applied to oxide film formation, polysilicon film formation, silane-ammonia processing, silane-hydrogen processing, oxide film processing, silane-oxygen processing, other CVD processing, and further etching processing.

### EXAMPLES

### Example 1

When performing SiN film formation processing on the surface of a substrate G in the plasma processing apparatus 1 according to the embodiments of the present invention explained with FIG. 2 and so on, changes of positions of electric fields E in the rectangular waveguides 35 and influences on plasma generated in the processing chamber 4 were studied while changing the height a of the upper face member 45 of a rectangular waveguide 35. Note that in Example 1, the inside diameter of the processing chamber 4 of the plasma processing apparatus 1 is 720 mm×720 mm, and a glass substrate G with a size of 400 mm×500 mm is mounted on the susceptor 10 to conduct an experiment.

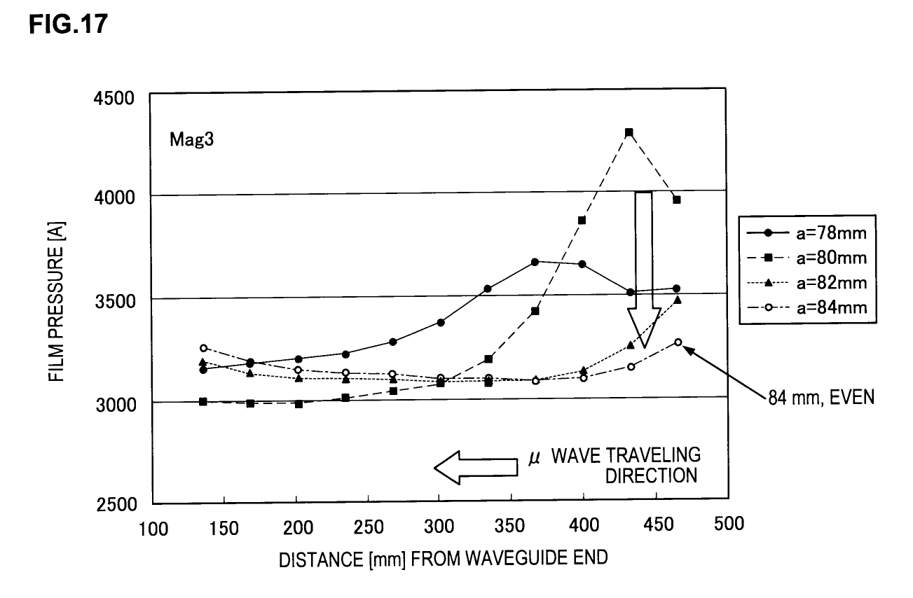

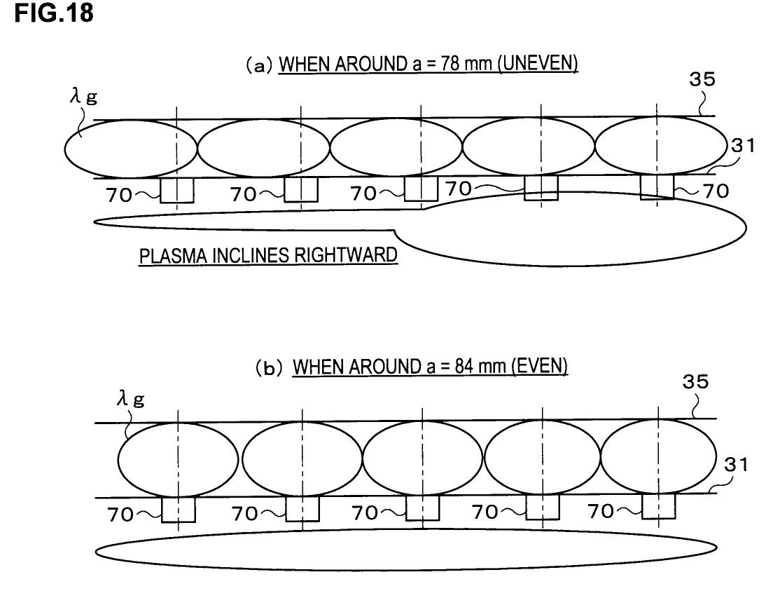

Changes of a film thickness A with respect to a distance from a rear end of the rectangular waveguide 35 were studied regarding an SiN film formed on the surface of a substrate C, and then FIG. 17 was obtained. FIG. 17 represents a relationship between the film thickness (A) of the SiN film and a distance (mm) from the rear end of the rectangular waveguide 35. When the plasma density is high, the deposition rate becomes large, and consequently, the film thickness of the SiN film becomes thick. Thus, it can be conceived that the film thickness and the plasma density are in a proportional relationship. When the film thickness A at each height were studied while changing the height a of the upper face member 45 of the rectangular waveguide 35 to 78 mm, 80 mm, 82 mm, and 84 mm, a change of the film thickness A with respect to the distance from the rear end of the rectangular waveguide 35 became the smallest when a=84 mm, and an SiN film with an even film thickness A was formed on the entire surface of the substrate G. On the other hand, when a=78 mm, 80 mm, and 82 mm, the film thickness A became thick on a near side of the rectangular waveguide 35 in all the cases, and the film thickness A decreased more on the rear end side of the rectangular waveguide 35. Except when a=84 mm, it is conceivable that the interval between antinode portions of a standing wave (distance that is half the guide wavelength λg) do not match with the predetermined interval (λg′/2) between the slots 70.

Changes of a standing wave generated in the rectangular waveguide 35 when the height a of the upper face member 45 of the rectangular waveguide 35 is near 78 mm and 84 mm are shown schematically in FIG. 18. When near a=78 mm, the interval (λg/2) between antinode portions of the standing wave becomes relatively long, and hence as shown in FIG. 18(a), the interval between antinode portions of the standing wave became longer than the interval (λg′/2) between the slots 70 formed in the lower face (slot antenna 31) of the rectangular waveguide 35. Accordingly, antinode portions of the standing wave are deviated from the positions of the slots 70 more on the front end side of the rectangular waveguide 35. This exerts an influence that microwaves propagating from the slots 70 to the dielectrics 32 decrease on the rear end side of the rectangular waveguide 35, unevenness in electric field energy occurs and makes the plasma become uneven, and consequently the film formation becomes uneven. On the other hand, when near a=84 mm, as shown in FIG. 18(b), the antinode portions of the standing wave substantially match with the positions of the slots 70 formed in the lower face (slot antenna 31) of the rectangular waveguide 35. Accordingly, even plasma was generated across the longitudinal direction of the rectangular waveguide 35 in the processing chamber 4, and the film thickness also became substantially even. Thus, it was understood that, by changing the height a of the upper face member 45 of the rectangular waveguide 35 and adjusting the actual guide wavelength λg of a microwave propagating in the rectangular waveguide 35, the antinode portions of a standing wave can be matched with the positions of the slots 70, and a microwave can be propagated efficiently to the dielectrics 32 on the upper face of the processing chamber 4.

### Example 2

In the plasma processing apparatus 1 according to the embodiments of the present invention explained with FIG. 12 and so on, formation processing of an amorphous Si film was performed on the surface of a substrate G. At this time, three standing wave measuring units 200 were attached at appropriate intervals on the upper face of a rectangular waveguide 35 along the longitudinal direction 220, and the interval between antinode portions of a standing wave was detected by each of the standing wave measuring units 200. Further, the interval (height of the upper face member 45) a between the E faces of the rectangular waveguide 35 was changed in steps of da=−4 mm, +2 mm, +5 mm, +8 mm, +12 mm with respect to a reference height 82 mm.

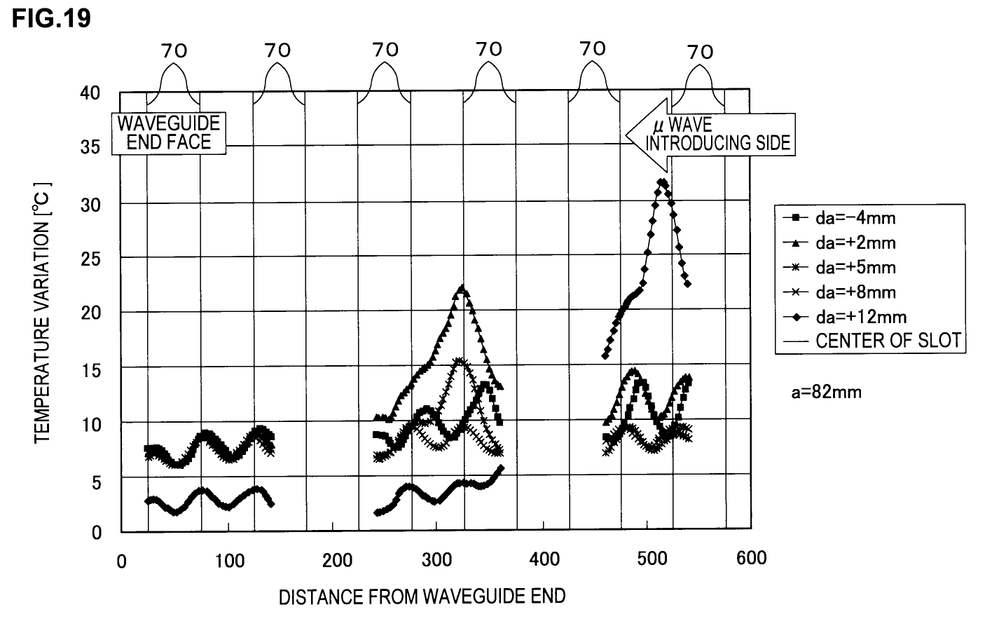

First, a relationship between temperature variations in the respective conductive members 202 in the three standing wave measuring units 200 and a distance from the rear end of the rectangular waveguide 35 was checked. As shown in FIG. 19, with any da, the temperatures in the respective conductive members 202 varied periodically in a substantially sinusoidal shape with respect to the distance from the rear end of the rectangular waveguide 35, and peak temperatures were exhibited at substantially constant intervals. However, positions exhibiting the peak temperatures (distances from the rear end of the rectangular waveguide 35) do not match with each other for the respective da, and the interval of exhibiting a peak temperature was shifted by every da.

On the other hand, as explained previously with FIG. 4 and so on, the E-face currents I flowing in width directions of the conductive members 202 due to the influence of a standing wave generated in the rectangular waveguide 35 repeats the maximum value +I in a positive direction and the maximum value −I in a negative direction by periods of the interval λg/2, which is half the guide wavelength λg. Accordingly, the period of a temperature variation (interval between antinode portions of a standing wave) detected by the measuring circuit 214 of a standing wave measuring unit 200 matches with this interval λg/2 which is half the guide wavelength λg. Therefore, it can be expected that, when the interval between antinode portions of a standing wave detected by this measuring circuit 214 is doubled, it becomes substantially equal to the guide wavelength λg.

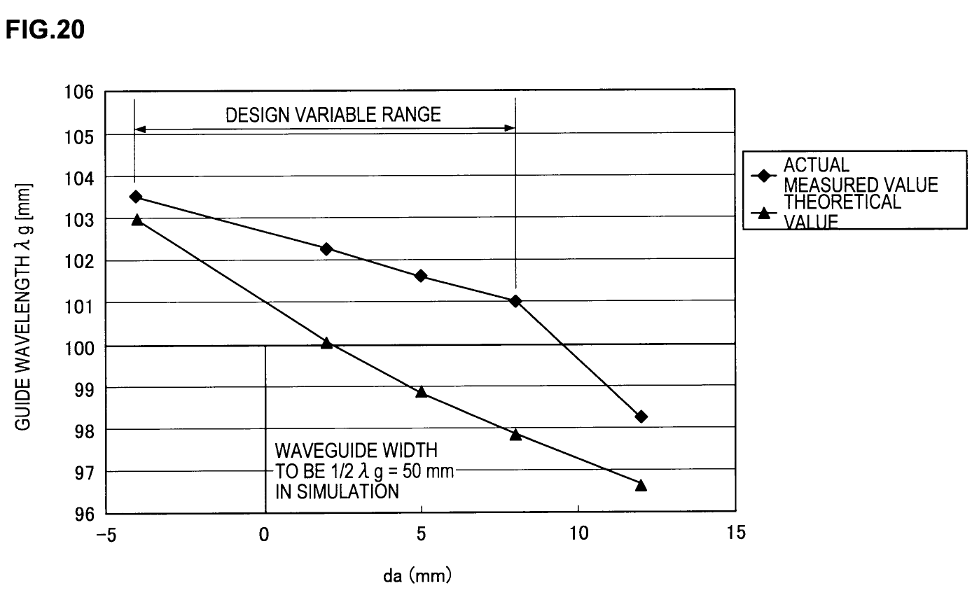

Accordingly, the guide wavelengths kg (actual measured values) obtained by doubling intervals between antinode portions of standing waves detected by the respective standing wave measuring units 200 with respective da are shown in FIG. 20. Note that intervals of exhibiting peak temperatures are shifted with respect to the respective da, and in FIG. 20 a relationship of the both is shown with the horizontal axis being da, and the vertical axis being the guide wavelength λg. The guide wavelength λg (actual measured value) obtained from periods of temperature variations exhibited a tendency to decrease as the da gets larger.

Further, theoretical values of the guide wavelength λg for the respective da were described together in FIG. 20. The both (the actual values and the theoretical values) matched substantially. Accordingly, it was demonstrated that the guide wavelength λg can be measured from temperature variations of the conductive members 202.

### INDUSTRIAL APPLICABILITY

The present invention can be applied to CVD processing and etching processing for example.

1. A standing wave measuring unit for measuring a standing wave generated in a waveguide which propagates an electromagnetic wave, the unit comprising:
a conductive member disposed along a longitudinal direction of the waveguide to form at least a part of pipe walls of the waveguide; and
a temperature detecting means for detecting a temperature of the conductive member at plural positions in the longitudinal direction of the waveguide.

2. The standing wave measuring unit according to claim 1, wherein
the waveguide is a rectangular waveguide.

3. The standing wave measuring unit according to claim 2, wherein
the conductive member is disposed on a narrow wall face of the rectangular waveguide.

4. The standing wave measuring unit according to claim 1, wherein
the conductive member has a plate shape, and a thickness d of the conductive member satisfies a relationship of following expression (1) when an angular frequency of an electromagnetic wave propagating in the waveguide is ω, magnetic permeability of the conductive member in which a temperature is measured is μ, and resistivity thereof is ρ.
3×(2ρ/(ωμ))^{1/2}<d<14×(2ρ/(ωμ))^{1/2} (1)

5. The standing wave measuring unit according to claim 1, wherein
the conductive member has a plate shape, and a plurality of holes are formed therein.

6. The standing wave measuring unit according to claim 1, wherein
the conductive member is a mesh formed by metal.

7. The standing wave measuring unit according to claim 1, wherein
the conductive member has a structure in which a plurality of conductive parts extending in a direction orthogonal to the longitudinal direction of the waveguide are disposed in parallel at predetermined intervals.

8. The standing wave measuring unit according to claim 1, further comprising
a temperature regulating mechanism controlling a temperature in a periphery of the conductive member.

9. The standing wave measuring method according to claim 8, wherein
the temperature detecting unit is capable of measuring a temperature in a periphery of the conductive member.

10. The standing wave measuring method according to claim 8, further comprising
another temperature detecting means for measuring a temperature in a periphery of the conductive member.

11. The standing wave measuring unit according to claim 1, wherein
the temperature detecting means comprises a temperature sensor detecting a temperature of the conductive member, a measuring circuit processing an electric signal from the temperature sensor, and a wiring electrically connecting the temperature sensor and the measuring circuit, and
a plurality of the temperature sensors are disposed along the longitudinal direction of the waveguide.

12. The standing wave measuring unit according to claim 11, wherein
the wiring comprises a heat transfer suppressing unit suppressing transfer of heat via the wiring.

13. The standing wave measuring unit according to claim 11, wherein
the temperature sensor comprises a plurality of electrodes, and at least one of the plurality of electrodes is electrically short-circuited to the waveguide.

14. The standing wave measuring unit according to claim 11, wherein
a printed circuit board comprising the temperature sensor is attached to the conductive member.

15. The standing wave measuring unit according to claim 11, wherein
the temperature sensor is disposed outside the waveguide.

16. The standing wave measuring unit according to claim 11, further comprising
a heat transfer path transferring a temperature of the conductive member to the temperature sensor.

17. The standing wave measuring unit according to claim 11, wherein
the temperature sensor is one of thermistor, resistance temperature sensor, diode, transistor, temperature measuring IC, thermocouple, and Peltier element.

18. The standing wave measuring unit according to claim 1, wherein
the temperature detecting unit is structured to move along the longitudinal direction of the waveguide one or more temperature sensors detecting a temperature of the conductive member.

19. The standing wave measuring unit according to claim 18, wherein
the temperature sensor is disposed outside the waveguide.

20. The standing wave measuring unit according to claim 18, wherein
the temperature sensor is an infrared temperature sensor.

21. The standing wave measuring unit according to claim 1, wherein
the temperature detecting means is an infrared camera.

22. The standing wave measuring unit according to claim 1, wherein
one of guide wavelength, frequency, standing wave ratio, propagation constant, attenuation constant, phase constant, propagation mode, incident power, reflection power, and transmitted power of an electromagnetic wave propagating in the waveguide or one of reflection coefficient and impedance of a load connected to the waveguide is measured.

23. The standing wave measuring unit according to claim 1, wherein
a plurality of positions in the longitudinal direction of the waveguide are fixed.

24. The standing wave measuring unit according to claim 1, wherein
a plurality of positions in the longitudinal direction of the waveguide are movable.

25. An electromagnetic wave utilization apparatus comprising an electromagnetic wave supply source for generating an electromagnetic wave, a waveguide for propagating an electromagnetic wave, and a wave utilization means for utilizing the electromagnetic wave supplied from the waveguide to perform predetermined processing, wherein
the waveguide is provided with the standing wave measuring unit according to claim 1.

26. A standing wave measuring unit for measuring a standing wave generated in a waveguide which propagates an electromagnetic wave, the unit comprising:
a conductive member disposed along a longitudinal direction of the waveguide to form at least a part of pipe walls of the waveguide; and
a current detecting means for detecting a current flowing in the conductive member at plural positions in the longitudinal direction of the waveguide.

27. An electromagnetic wave utilization apparatus comprising an electromagnetic wave supply source for generating an electromagnetic wave, a waveguide for propagating an electromagnetic wave, and a wave utilization means for utilizing the electromagnetic wave supplied from the waveguide to perform predetermined processing, wherein
the waveguide is provided with the standing wave measuring unit according to claim 26.

28. A standing wave measuring method for measuring a standing wave generated in a waveguide which propagates an electromagnetic wave, the method comprising:
detecting a distribution of temperatures in a conductive member forming at least a part of pipe walls of the waveguide with respect to a longitudinal direction of the waveguide; and
measuring a standing wave based on the temperature distribution.

29. The standing wave measuring method according to claim 28, wherein
a reference temperature of the conductive member is measured in a state that no electromagnetic wave is propagating in the waveguide, and the distribution of temperatures in the conductive member is detected by a temperature difference from the reference temperature.

30. The standing wave measuring method according to claim 28, wherein
one of guide wavelength, frequency, standing wave ratio, propagation constant, attenuation constant, phase constant, propagation mode, incident power, reflection power, and transmitted power of an electromagnetic wave propagating in the waveguide or one of reflection coefficient and impedance of a load connected to the waveguide is measured.

31. A standing wave measuring method of measuring a standing wave generated in a waveguide which propagates an electromagnetic wave, the method comprising:
detecting an electric current flowing in a conductive member forming at least a part of pipe walls of the waveguide; and
measuring a standing wave based on a distribution of the current with respect to a longitudinal direction of the waveguide.

32. The standing wave measuring method according to claim 31, wherein
one of guide wavelength, frequency, standing wave ratio, propagation constant, attenuation constant, phase constant, propagation mode, incident power, reflection power, and transmitted power of an electromagnetic wave propagating in the waveguide or one of reflection coefficient and impedance of a load connected to the waveguide is measured.

33. A plasma processing apparatus provided with a processing vessel in which plasma is excited for substrate processing, a microwave supply source supplying a microwave for exciting plasma in the processing vessel, a waveguide in which a plurality of slots are opened and which is connected to the microwave supply source, and a dielectric plate which propagates a microwave emitted from the slots to plasma, the apparatus comprising
the standing wave measuring unit according to claim 1 for measuring a standing wave generated in the waveguide.

34. The plasma processing apparatus according to claim 33, further comprising
a wavelength control mechanism controlling a wavelength of a microwave propagated in the waveguide.

35. The plasma processing apparatus according to claim 34, wherein
the waveguide is a rectangular waveguide, and the wavelength control mechanism moves a narrow wall face of the rectangular waveguide vertically with respect to a propagating direction of a microwave in the waveguide.

36. A plasma processing method for performing substrate processing by emitting a microwave propagated in a waveguide from a plurality of slots opened in the waveguide and propagating the microwave to a dielectric plate and exciting plasma in a processing vessel, the method comprising:
detecting a distribution of temperatures in a conductive member forming at least a part of pipe walls of the waveguide with respect to a longitudinal direction of the waveguide and measuring a standing wave based on the temperature distribution; and
controlling a wavelength of a microwave propagated in the waveguide based on the measured standing wave.

37. The plasma processing method according to claim 36, wherein
the waveguide is a rectangular waveguide, and the wavelength of the microwave propagated in the waveguide is controlled by moving a narrow wall face of the rectangular waveguide vertically with respect to a propagating direction of a microwave in the waveguide.

38. The plasma processing method according to claim 36, wherein
the wavelength of the microwave propagated in the waveguide is controlled so that antinode portions of a standing wave generated in the waveguide match with the slots.
